(19) United States
(12) Patent Application Publication
(10) Pub. No.: US 2025/0210499 A1
(43) Pub. Date: Jun. 26, 2025

(54) SEMICONDUCTOR PACKAGE

(71) Applicant: SAMSUNG ELECTRONICS CO., LTD., Suwon-si (KR)

(72) Inventors: Minjung KIM, Suwon-si (KR); Ilho Kim, Suwon-si (KR); Jihyun Park, Suwon-si (KR)

(73) Assignee: SAMSUNG ELECTRONICS CO., LTD., Suwon-si (KR)

(21) Appl. No.: 18/778,302

(22) Filed: Jul. 19, 2024

(30) Foreign Application Priority Data
Dec. 20, 2023 (KR) 10-2023-0187522

(51) Int. Cl. H01L 23/498; H01L 23/00; H01L 23/31; H01L 23/48; H01L 25/065; H01L 25/18; H10B 80/00

(52) U.S. Cl. CPC H01L 23/49838; H01L 23/3135; H01L 23/481; H01L 23/49822; H01L 23/49833; H01L 24/16; H01L 25/0657; H01L 25/18; H01L 2224/16145; H01L 2224/16238; H01L 2225/06513; H01L 2225/06517; H01L 2225/06541; H01L 2924/1431; H01L 2924/1436; H01L 2924/1437; H10B 80/00

(57) ABSTRACT

A semiconductor package includes: a first substrate; a lower semiconductor chip on the first substrate and including a through via; an upper semiconductor chip on the lower semiconductor chip and connected to the through via; a first lower conductive structure on the first substrate and laterally spaced apart from the lower semiconductor chip; a second lower conductive structure on the first substrate and laterally spaced apart from the lower semiconductor chip and the first lower conductive structure; an upper conductive structure on the second lower conductive structure; a conductive layer in direct physical contact with a top surface of the upper semiconductor chip and electrically connected to the first lower conductive structure; and a second substrate on the conductive layer and electrically connected to the upper conductive structure.

### CROSS-REFERENCE TO RELATED APPLICATION

This application is based on and claims priority under 35 U.S.C. § 119 to Korean Patent Application No. 10-2023-0187522, filed on Dec. 20, 2023, in the Korean Intellectual Property Office, the disclosure of which is incorporated by reference herein in its entirety.

### BACKGROUND

The present disclosure relates to a semiconductor package, and more particularly, to a semiconductor package including a redistribution substrate.

A semiconductor package is an integrated circuit chip implemented in a form suitable for use in electronic products. Typically, in a semiconductor package, semiconductor chips are mounted on a printed circuit board are electrically connected to each other using bonding wires or bumps. According to the development of the electronics industry, various researches are being conducted for improved reliability, higher integration, and miniaturization of semiconductor packages.

### SUMMARY

One or more embodiments of the present disclosure provide a semiconductor package which may have improved thermal characteristics and electrical characteristics.

Further, one or more embodiments of the present disclosure provide a semiconductor package which may have improved warpage characteristics.

According to an aspect of the present disclosure, a semiconductor package is provided and includes: a first substrate; a lower semiconductor chip on the first substrate and including a through via; an upper semiconductor chip on the lower semiconductor chip and connected to the through via; a first lower conductive structure on the first substrate and laterally spaced apart from the lower semiconductor chip; a second lower conductive structure on the first substrate and laterally spaced apart from the lower semiconductor chip and the first lower conductive structure; an upper conductive structure on the second lower conductive structure; a conductive layer in direct physical contact with a top surface of the upper semiconductor chip and electrically connected to the first lower conductive structure; and a second substrate on the conductive layer and electrically connected to the upper conductive structure.

According to an aspect of the present disclosure, a semiconductor package is provided and includes: a first redistribution substrate; a lower semiconductor chip on the first redistribution substrate and including a through via; an upper semiconductor chip on the lower semiconductor chip and connected to the lower semiconductor chip; a first lower conductive structure on the first redistribution substrate and laterally spaced apart from the lower semiconductor chip; and a conductive layer in physical contact with a top surface of the upper semiconductor chip and electrically connected to the first lower conductive structure.

According to an aspect of the present disclosure, a semiconductor package is provided and includes: a first redistribution substrate including a first insulation layer, a first seed pattern, and a first conductive pattern on the first seed pattern, the first insulation layer including a photosensitive polymer; solder ball terminals on a bottom surface of the first redistribution substrate; a lower semiconductor chip on a top surface of the first redistribution substrate and including a lower pad, a through via, and an upper pad; an upper semiconductor chip on a top surface of the lower semiconductor chip and connected to the through via; a first lower conductive structure on the first redistribution substrate and laterally spaced apart from the lower semiconductor chip; a second lower conductive structure on the first redistribution substrate and laterally spaced apart from the lower semiconductor chip and the first lower conductive structure, the first lower conductive structure being between the lower semiconductor chip and the second lower conductive structure; an upper conductive structure on the second lower conductive structure; a molding film on the first redistribution substrate and covering sidewalls of the lower semiconductor chip, sidewalls of the first lower conductive structure, and sidewalls of the second lower conductive structure, the molding film being spaced apart from a top surface of the upper semiconductor chip; a conductive layer on the upper semiconductor chip and in direct contact with the top surface of the upper semiconductor chip; and a second redistribution substrate on the molding film and the conductive layer and including a second insulation layer, second seed patterns, second redistribution patterns on the second seed patterns, and second redistribution pads, wherein the conductive layer includes: a seed layer in direct contact with the top surface of the upper semiconductor chip; and a metal layer on the seed layer.

### BRIEF DESCRIPTION OF THE DRAWINGS

Embodiments of the present disclosure will be more clearly understood from the following detailed description taken in conjunction with the accompanying drawings, in which:

FIG. 1A is a diagram showing a semiconductor package according to embodiments;

FIG. 1B is a cross-sectional view taken along a line I-I′ of FIG. 1A;

FIG. 1C is an enlarged view of a region II of FIG. 1B;

FIG. 1D is a cross-sectional view illustrating a semiconductor package according to embodiments;

FIG. 1E is a plan view of a semiconductor package according to embodiments;

FIG. 1F is a cross-sectional view illustrating a semiconductor package according to embodiments;

FIG. 1G is a cross-sectional view illustrating a semiconductor package according to embodiments;

FIG. 2A is a plan view of a semiconductor package according to embodiments;

FIG. 2B is a cross-sectional view taken along a line I-I′ of FIG. 2A;

FIG. 3A is a plan view of a semiconductor package according to embodiments;

FIG. 3B is a cross-sectional view taken along a line III-III′ of FIG. 3A;

FIG. 4A is a plan view of a semiconductor package according to embodiments;

FIG. 4B is a cross-sectional view taken along a line I-I′ of FIG. 4A;

FIG. 4C is an enlarged view of a region IV of FIG. 4B;

FIG. 4D is a diagram illustrating a first upper conductive structure according to embodiments;

FIG. 4E is a diagram illustrating a first upper conductive structure according to embodiments;

FIG. 4F is a diagram illustrating a first upper conductive structure according to embodiments;

FIG. 4G is a diagram illustrating a first upper conductive structure according to embodiments;

FIG. 4H is a cross-sectional view illustrating a semiconductor package according to embodiments;

FIG. 4I is a plan view of a semiconductor package according to embodiments;

FIG. 4J is a cross-sectional view of a semiconductor package according to embodiments;

FIG. 5 is a diagram illustrating a semiconductor package according to embodiments;

FIGS. 6A to 6I are diagrams illustrating a method of manufacturing a semiconductor package, according to embodiments; and

FIGS. 7A to 7J are diagrams illustrating a method of manufacturing a semiconductor package, according to embodiments.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

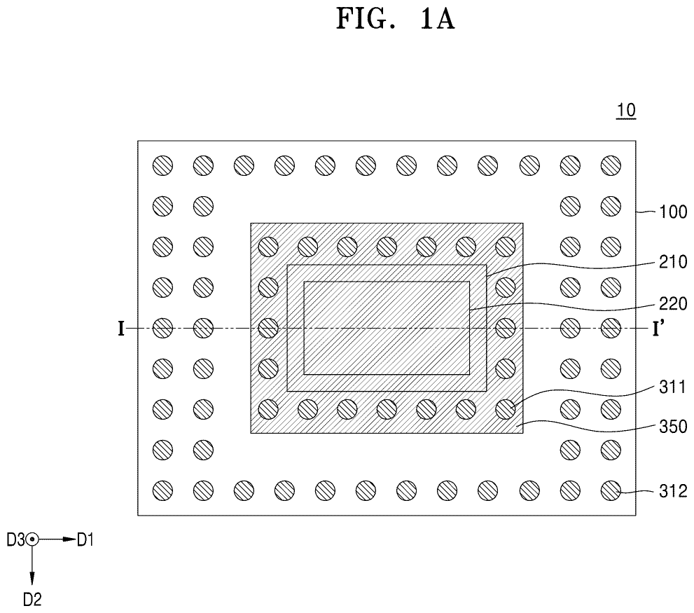

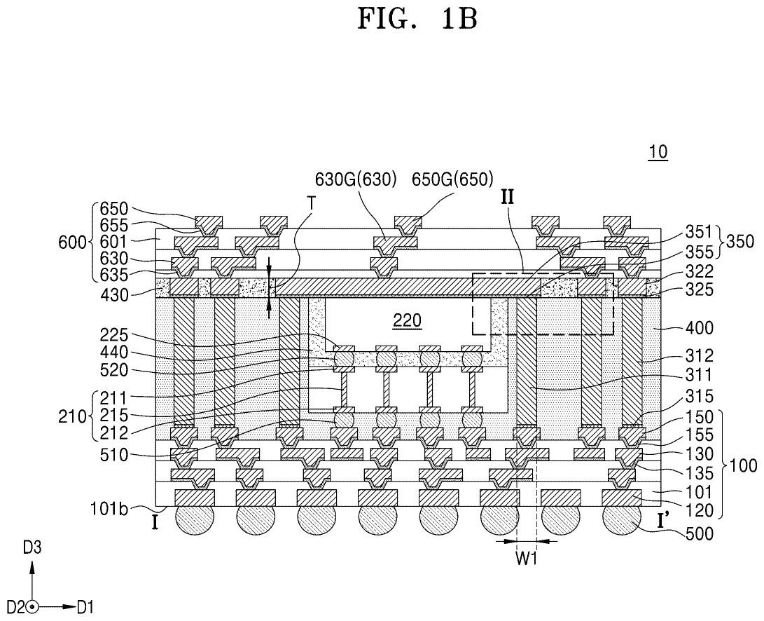

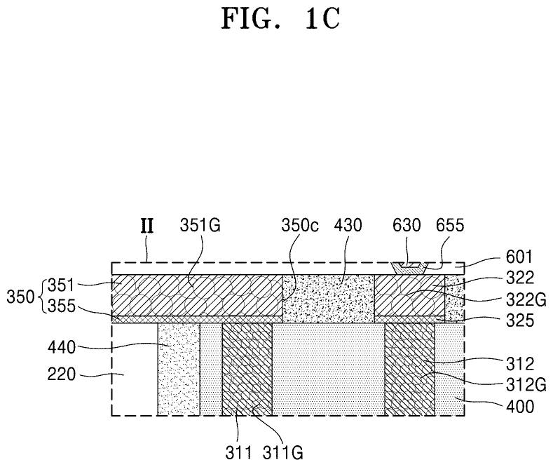

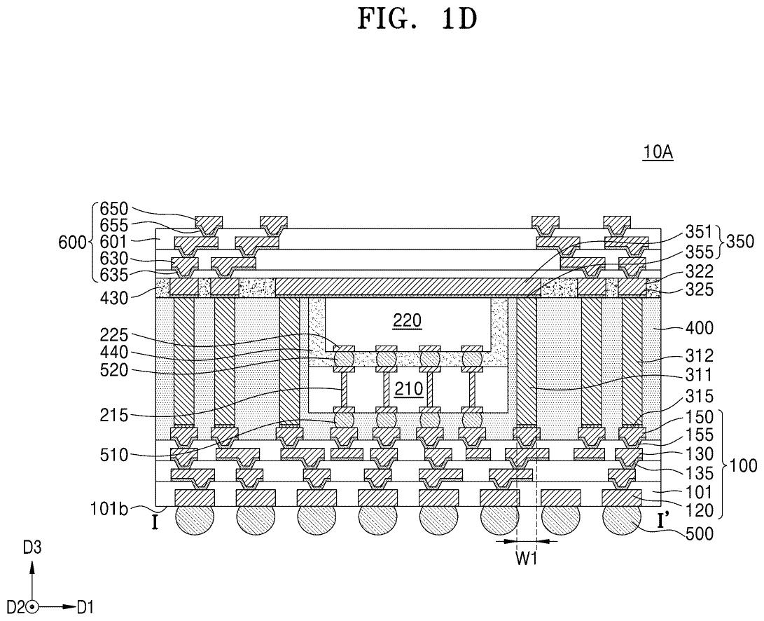

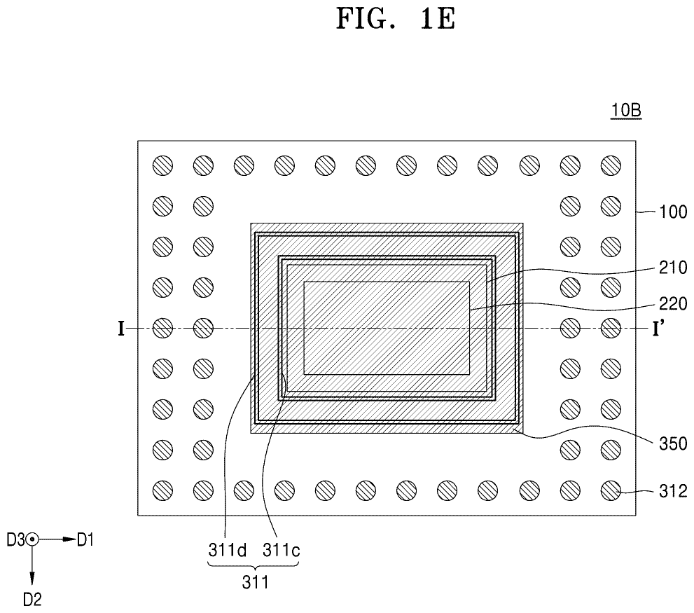

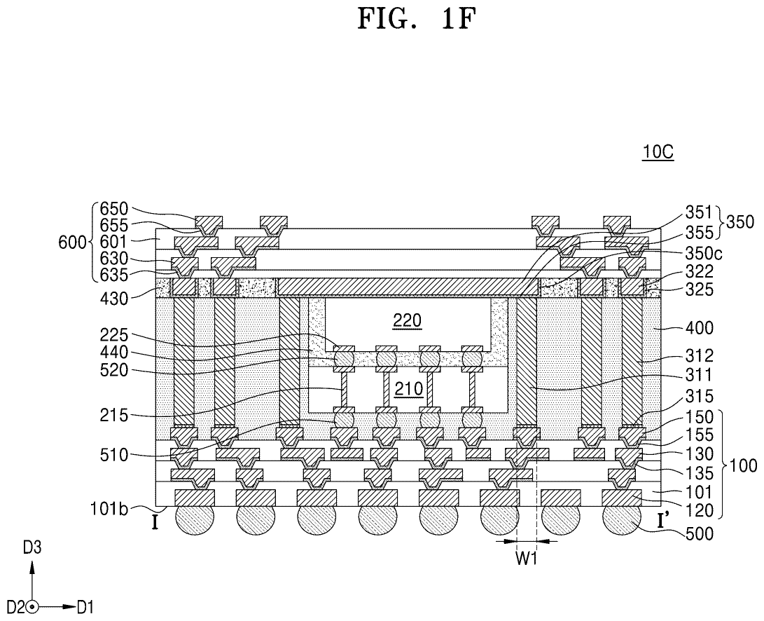

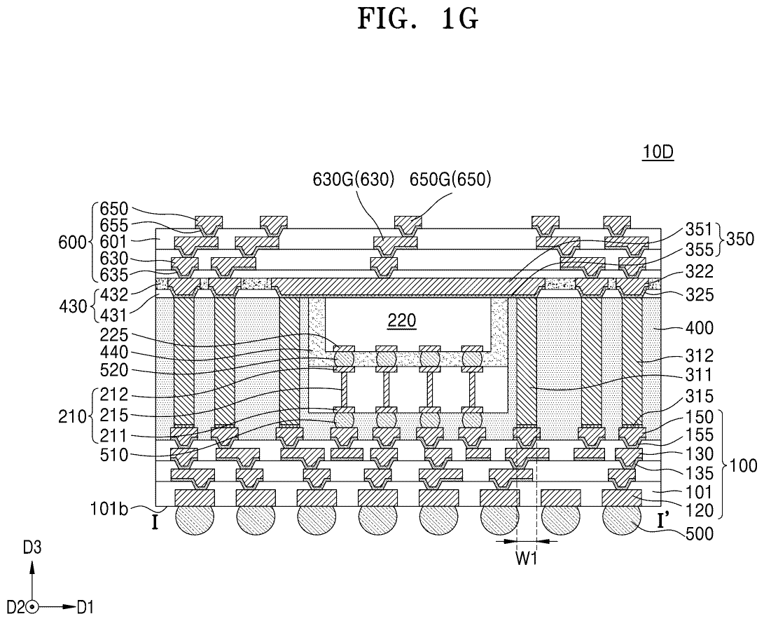

FIG. 1A is a diagram showing a semiconductor package according to embodiments. FIG. 1B is a cross-sectional view taken along a line I-I′ of FIG. 1A. FIG. 1C is an enlarged view of a region II of FIG. 1B.

Referring to FIGS. 1A to 1C, a semiconductor package 10 may include a first substrate 100, solder ball terminals 500, a lower semiconductor chip 210, an upper semiconductor chip 220, first lower conductive structures 311, second lower conductive structures 312, an upper conductive structure, lower solder bumps 510, first upper solder bumps 520, a molding film 400, an insulation sealing film 430, and a second substrate 600. The semiconductor package 10 may be a lower package. The upper conductive structure may include second upper conductive structures 322.

The first substrate 100 may include an edge region and a center region. The edge region of the first substrate 100 may surround the center region in a plan view. For example, the first substrate 100 may be a redistribution substrate. In another example, the first substrate 100 may include a printed circuit board. Hereinafter, for convenience, the case where the first substrate 100 is a redistribution substrate is illustrated, but embodiments of the present disclosure are not limited thereto. When the first substrate 100 is a redistribution substrate, the first substrate 100 may include one or more first insulation layers 101, under bump patterns 120, first redistribution patterns 130, first seed patterns 135, first seed pads 155, and first redistribution pads 150. Electrical connection to the first substrate 100 may mean electrical connection to any one of the first redistribution patterns 130. Mutual electrical connection between two components may include a direct connection or an indirect connection through another component. The first redistribution pads 150 may be provided in an uppermost one of the first insulation layers 101 and extend onto the top surface of the uppermost one of the first insulation layers 101. A first direction D1 may be parallel to a bottom surface 101b of a lowermost one of the first insulation layers 101. A second direction D2 may be parallel to the bottom surface 101b of the lowermost one of the first insulation layers 101 and may be substantially perpendicular to the first direction D1. A third direction D3 may be substantially perpendicular to the first direction D1 and the second direction D2. The third direction D3 may be a vertical direction. Detailed descriptions of the first insulation layer 101, the under bump patterns 120, the first redistribution patterns 130, the first seed patterns 135, the first seed pads 155, and the first redistribution pads 150 will be given below.

The solder ball terminals 500 may be arranged on the bottom surface of the first substrate 100. For example, the solder ball terminals 500 may be arranged on the bottom surfaces of the under bump patterns 120 and connected to the under bump patterns 120, respectively. The solder ball terminals 500 may be electrically connected to the first redistribution patterns 130 through the under bump patterns 120, respectively. The solder ball terminals 500 may include a solder material. The solder material may include, for example, tin, bismuth, lead, silver, or an alloy thereof. The solder ball terminals 500 may include signal solder balls, ground solder balls, and power solder balls.

The lower semiconductor chip 210 may be mounted on the top surface of the first substrate 100. For example, the lower semiconductor chip 210 may be disposed on the center region of the first substrate 100 in a plan view. For example, the lower semiconductor chip 210 may be a lower chiplet. A chiplet may include at least one of intellectual property (IP) block units formed by dividing a logic semiconductor chip by functions. The logic semiconductor chip may constitute one processor and may operate as one processor. Unlike the logic semiconductor chip, each chiplet may not operate as an independent processor, but chiplets may be connected to one another and operate as at least one processor. In other words, the processor may include chiplets connected to one another. The lower semiconductor chip 210 may function as a logic chip or a buffer chip. In contrast, the lower semiconductor chip 210 may be a memory chip such as static random access memory (SRAM) or dynamic random access memory (DRAM).

The lower semiconductor chip 210 may include lower pads 211, through vias 215, and upper pads 212. The lower pads 211 and the upper pads 212 may be provided on the bottom surface and the top surface of the lower semiconductor chip 210, respectively. The lower pads 211 and the upper pads 212 may be electrically connected to integrated circuits of the lower semiconductor chip 210. The lower pads 211 or the upper pads 212 may be chip pads. The through vias 215 are provided in the lower semiconductor chip 210 and may each connect one of the lower pads 211 to one of the upper pads 212. The through vias 215 may be further electrically connected to integrated circuits of the lower semiconductor chip 210. When a component is electrically connected to a semiconductor chip, it may mean that the component is electrically connected to integrated circuits through chip pads of the semiconductor chip. The through vias 215 may include signal vias. For example, the through vias 215 may transmit and receive electrical signals such as data signals to and from the upper semiconductor chip 220.

The semiconductor package 10 may further include lower solder bumps 510. The lower solder bumps 510 are provided between the first substrate 100 and the lower semiconductor chip 210 and may be connected to the first redistribution pads 150 and the lower pads 211. Therefore, the lower semiconductor chip 210 may be electrically connected to the first substrate 100 through the lower solder bumps 510. The lower solder bumps 510 may include solder balls. The lower solder bumps 510 may include a solder material. The lower solder bumps 510 may further include pillar patterns, and the pillar patterns may include a metal such as copper. The pillar patterns may be arranged between the lower semiconductor chip 210 and the solder balls.

According to embodiments, the semiconductor package 10 may further include an underfill film. The underfill film may be provided in a first gap region between the first substrate 100 and the lower semiconductor chip 210 and cover the sidewalls of the lower solder bumps 510. The underfill film may include an insulation polymer such as an epoxy polymer.

The upper semiconductor chip 220 may be provided on the top surface of the lower semiconductor chip 210. The upper semiconductor chip 220 may be a logic chip or a buffer chip. For example, the upper semiconductor chip 220 may be an upper chiplet. Specifically, when the lower semiconductor chip is a lower chiplet, the upper semiconductor chip may be an upper chiplet. Alternatively, the upper semiconductor chip 220 may be a memory chip. The width of the upper semiconductor chip 220 may be smaller than the width of the lower semiconductor chip 210.

The upper semiconductor chip 220 may include second integrated circuits and chip pads 225. The second integrated circuits are provided within the upper semiconductor chip 220 and may be arranged adjacent to the bottom surface of the upper semiconductor chip 220. The chip pads 225 are arranged on the bottom surface of the upper semiconductor chip 220 and may be electrically connected to second integrated circuits.

The first upper solder bumps 520 may be provided between the lower semiconductor chip 210 and the upper semiconductor chip 220 and connected to the upper pads 212 and the chip pads 225 of the upper semiconductor chip 220. The first upper solder bumps 520 may include solder balls. The first upper solder bumps 520 may further include pillar patterns, and the pillar patterns may include a metal such as copper. The upper semiconductor chip 220 may be electrically connected to the through vias 215 through the first upper solder bumps 520. The widths and pitches of the first upper solder bumps 520 may be relatively small.

The semiconductor package 10 may further include an internal molding film 440. The internal molding film 440 is provided on the top surface of the lower semiconductor chip 210 and may cover the sidewalls of the upper semiconductor chip 220. The top surface of the internal molding film 440 may be coplanar with the top surface of the upper semiconductor chip 220. The sidewalls of the internal molding film 440 may be vertically aligned with the sidewalls of the lower semiconductor chip 210, but embodiments of the present disclosure are not limited thereto. The internal molding film 440 may further extend into a second gap region between the lower semiconductor chip 210 and the upper semiconductor chip 220 and cover the sidewalls of the first upper solder bumps 520. The internal molding film 440 may include an insulation polymer such as an epoxy molding compound (EMC).

Lower conductive structures are provided on the first substrate 100 and may be laterally spaced apart from the lower semiconductor chip 210 and the upper semiconductor chip 220. Any two components laterally spaced apart from each other may mean that the two components are horizontally spaced from each other. Being “horizontal” may mean being parallel to the bottom surface 101b of the lowermost one of the first insulation layers 101. The lower conductive structures may include the first lower conductive structures 311 and the second lower conductive structures 312. The first lower conductive structures 311 and the second lower conductive structures 312 may be arranged on and connected to corresponding ones of the first redistribution pads 150, respectively. Therefore, the first lower conductive structures 311 and the second lower conductive structures 312 may be connected to the first substrate 100. Certain components having widths, heights, and levels identical to each other may mean that the components are identical to each other within a margin of error in the process. The first lower conductive structures 311 and the second lower conductive structures 312 may include a metal, such as copper.

The first lower conductive structures 311 may each have a first width W1. Since the first lower conductive structures 311 function as a path for a ground voltage and the through vias 215 include signal vias, the first width W1 may be greater than the width of each of the through vias 215. For example, the first width W1 may be from about 50 μm to about 500 μm. Since the first width W1 is 50 μm or greater, the power characteristics of the semiconductor package 10 may be improved. Also, the first lower conductive structures 311 may be easily manufactured. Since the first width W1 is less than or equal to 500 μm, the arrangement of the lower semiconductor chip 210 and the second lower conductive structures 312 may not be restricted by the first lower conductive structures 311.

The first lower conductive structures 311 may be arranged between the lower semiconductor chip 210 and the second lower conductive structures 312. The first lower conductive structures 311 may include metal posts each having a cylindrical shape. The first lower conductive structures 311 may surround the lower semiconductor chip 210 in a plan view. For example, the first lower conductive structures 311 may be arranged between four side surfaces of the lower semiconductor chip 210 and the side surfaces of the first substrate 100 in a plan view. As shown in FIG. 1B, any one of the first lower conductive structures 311 may be disposed on a first side of the lower semiconductor chip 210, and another one of the first lower conductive structures 311 may be disposed on a second side of the lower semiconductor chip 210. The second side of the lower semiconductor chip 210 may face away from the first side of the lower semiconductor chip 210. The first lower conductive structures 311 may include a metal such as copper.

The second lower conductive structures 312 may be disposed on the edge region of the first substrate 100 in a plan view and electrically connected to the first substrate 100. The edge region of the first substrate 100 may be provided between the center region of the first substrate 100 and the side surfaces of the first substrate 100 in a plan view. The second lower conductive structures 312 may be laterally spaced apart from the lower semiconductor chip 210 and the first lower conductive structures 311. The first lower conductive structures 311 may be arranged between the lower semiconductor chip 210 and the second lower conductive structures 312 in a plan view. The second lower conductive structures 312 may include metal posts each having a cylindrical shape. The second lower conductive structures 312 may be electrically connected to the solder ball terminals 500, the lower semiconductor chip 210, or the upper semiconductor chip 220 through the first substrate 100.

The width of the second lower conductive structures 312 may be identical to or different from the first width W1. The height of the second lower conductive structures 312 may be substantially identical to the height of the first lower conductive structures 311. For example, top surfaces 312a of the second lower conductive structures 312 may be provided at a level substantially identical to those of top surfaces 311a of the first lower conductive structures 311 and the top surface of the lower semiconductor chip 210. A level of a certain component may refer to a vertical level, and a level difference between two components may be measured in the third direction D3. The second lower conductive structures 312 may include the same metal material as a metal material of the first lower conductive structures 311. The second lower conductive structures 312 may include copper, for example.

The semiconductor package 10 may further include lower seed patterns 315. The lower seed patterns 315 may be arranged on the bottom surfaces of the first lower conductive structures 311 and the second lower conductive structures 312. For example, the lower seed patterns 315 may be arranged between the first lower conductive structures 311 and the first redistribution pads 150 corresponding to the first lower conductive structures 311 and between the second lower conductive structures 312 and the first redistribution pads 150 corresponding to the second lower conductive structures 312. The lower seed patterns 315 may include a material different from materials constituting the first redistribution pads 150, the first lower conductive structures 311, and the second lower conductive structures 312. For example, the lower seed patterns 315 may include a conductive seed material. The conductive seed material may include a metal such as titanium and/or copper-titanium. According to embodiments, the lower seed patterns 315 may be omitted, and the first lower conductive structures 311 and the second lower conductive structures 312 may be directly connected to the first redistribution pads 150.

The molding film 400 may be provided on the first substrate 100. The molding film 400 may cover the sidewalls of the lower semiconductor chip 210, the sidewalls of the internal molding film 440, and the sidewalls of the first lower conductive structures 311 and the second lower conductive structures 312. The top surface of the molding film 400 may be coplanar with the top surfaces of the first lower conductive structures 311, the top surfaces of the second lower conductive structures 312, the top surface of the internal molding film 440, and the upper semiconductor chip 220. The molding film 400 may further extend into the first gap region between the first substrate 100 and the lower semiconductor chip 210 and seal the lower solder bumps 510. The molding film 400 may include an insulation polymer such as an EMC.

A conductive layer 350 may be disposed on the first lower conductive structures 311, the upper semiconductor chip 220, and the internal molding film 440. The conductive layer 350 may be in direct physical contact with the top surfaces of the first lower conductive structures 311, the top surface of the upper semiconductor chip 220, and the top surface of the internal molding film 440. According to an embodiment, the conductive layer 350 may further extend onto the molding film 400. The sidewalls 350c of the conductive layer 350 may not be vertically aligned with the sidewalls of the first lower conductive structures 311. For example, the sidewalls 350c of the conductive layer 350 may be provided on the molding film 400. In another example, the sidewalls 350c of the conductive layer 350 may be vertically aligned with the sidewalls of the first lower conductive structures 311. In this case, the conductive layer 350 may not extend onto the molding film 400. Vertical alignment of one component with another component may mean alignment within a margin of error in the process.

The conductive layer 350 may include a seed layer 355 and a metal layer 351. The seed layer 355 may be in direct physical contact with the top surfaces of the first lower conductive structures 311, the top surface of the upper semiconductor chip 220, and the top surface of the internal molding film 440. The seed layer 355 may further be in direct physical contact with the top surface of the molding film 400, but embodiments of the present disclosure are not limited thereto. The seed layer 355 may include a metal different from metals constituting the first lower conductive structures 311 and the metal layer 351. For example, the seed layer 355 may include a conductive seed material. The thickness of the seed layer 355 may be smaller than the thickness of the metal layer 351. The metal layer 351 may be formed on the seed layer 355. The metal layer 351 may include, for example, copper. The seed layer 355 may function as a barrier layer to prevent diffusion of a metal material contained in the metal layer 351. The sidewalls 350c of the conductive layer 350 may include the sidewalls of seed patterns and the sidewalls of the metal layer 351.

The conductive layer 350 may exhibit relatively high thermal conductivity. Since the conductive layer 350 is in direct contact with the top surface of the upper semiconductor chip 220, when the semiconductor package 10 is operated, heat generated by the upper semiconductor chip 220 may be quickly dissipated through the conductive layer 350. Therefore, the thermal characteristics of the upper semiconductor chip 220 may be improved. Heat generated by the lower semiconductor chip 210 may be quickly dissipated to the conductive layer 350 through the first upper solder bumps 520 and the upper semiconductor chip 220. Therefore, the thermal characteristics of the lower semiconductor chip 210 may be improved.

Since the conductive layer 350 is provided, restrictions on the thickness of the upper semiconductor chip 220 may be reduced. For example, even when the thickness of the upper semiconductor chip 220 is relatively large, the conductive layer 350 is in direct contact with the top surface of the upper semiconductor chip 220, and thus the heat generated by the upper semiconductor chip 220 may be quickly dissipated to the conductive layer 350. Therefore, the upper semiconductor chip 220 may have a relatively large thickness, thereby preventing warpage of the upper semiconductor chip 220. In the same regard, restrictions on the thickness of the lower semiconductor chip 210 may be reduced. The lower semiconductor chip 210 may have a relatively large thickness. Therefore, warpage of the lower semiconductor chip 210 may be reduced.

According to a comparative embodiment, when the conductive layer 350 and the first lower conductive structures 311 are omitted, stress may occur due to a difference between coefficients of thermal expansion (CTE) of semiconductor chips such as, for example, the lower semiconductor chip 210 and the upper semiconductor chip 220, and the molding film 400. Due to the stress, warpage of the lower semiconductor chip 210 or warpage of the upper semiconductor chip 220 may occur in the comparative embodiment.

According to embodiments, the semiconductor package 10 may include the conductive layer 350 and the first lower conductive structures 311. The thermal expansion coefficient of the conductive layer 350 and the first lower conductive structures 311 may be different from the thermal expansion coefficient of the molding film 400. The difference between the thermal expansion coefficient of the conductive layer 350 and the first lower conductive structures 311 and the thermal expansion coefficient of the molding film 400 may offset the difference between the thermal expansion coefficient of the lower semiconductor chip 210 and the upper semiconductor chip 220 and the thermal expansion coefficient of the molding film 400. Therefore, warpage of the lower semiconductor chip 210 and the upper semiconductor chip 220 due to difference between thermal expansion coefficients may be prevented. The semiconductor package 10 may exhibit improved durability and reliability.

According to embodiments, since the conductive layer 350 covers the top surface of the upper semiconductor chip 220, damage to the upper semiconductor chip 220 due to stress may be prevented. The stress may include, but is not limited to, residual stress.

A thickness T of the conductive layer 350 may be from about 10 μm to about 100 μm. The thickness T of the conductive layer 350 may be equal to the sum of the thickness of the seed layer 355 and the thickness of the metal layer 351. Since the thickness T of the conductive layer 350 is about 10 μm or greater, warpage of the lower semiconductor chip 210 and the upper semiconductor chip 220 may be sufficiently prevented. Also, restrictions on the thicknesses of the lower semiconductor chip 210 and the upper semiconductor chip 220 may be reduced. Since the thickness T of the conductive layer 350 is about 100 μm or less, the semiconductor package 10 may be miniaturized.

The conductive layer 350 may overlap the upper semiconductor chip 220 and the first lower conductive structures 311 in a plan view, as shown in FIG. 1A. The conductive layer 350 may have a rectangular shape in a plan view. However, the planar shape of the conductive layer 350 is not limited thereto and may be modified in various ways. The conductive layer 350 may contact from about 20% to about 100% of the top surface of the upper semiconductor chip 220 in a plan view. In other words, the contact area between the conductive layer 350 and the upper semiconductor chip 220 may be from about 20% to about 100% of the total planar area of the top surface of the upper semiconductor chip 220. Since the conductive layer 350 contacts more than 20% of the top surface of the upper semiconductor chip 220, the conductive layer 350 may sufficiently buffer the stress applied to the upper semiconductor chip 220. Therefore, the heat dissipation characteristics of the upper semiconductor chip 220 may be further improved.

The conductive layer 350 may be electrically connected to the first lower conductive structures 311. As shown in FIG. 1B, the first lower conductive structures 311 may receive voltage through the first redistribution patterns 130 and the solder ball terminals 500. The voltage may be a ground voltage. The first lower conductive structures 311 may function as a voltage supply path. For example, the first lower conductive structures 311 may be configured to supply a ground voltage to the conductive layer 350. Therefore, the first lower conductive structures 311 and the conductive layer 350 may shield the lower semiconductor chip 210 and the upper semiconductor chip 220 from electromagnetic interference (EMI). The EMI means that electromagnetic waves radiated or conducted from an electrical element cause interference in the reception/transmission function of another electrical element. According to embodiments, electromagnetic waves generated by the lower semiconductor chip 210 and the upper semiconductor chip 220 and other external electronic devices may be absorbed. Therefore, operation of other electronic devices may not interfere with the operation of the lower semiconductor chip 210 and the upper semiconductor chip 220. The other electronic devices may include, but are not limited to, electronic elements, semiconductor elements, other semiconductor packages, transmitters, receivers, passive elements, and/or active elements.

The first lower conductive structures 311 are arranged between the lower semiconductor chip 210 and the upper semiconductor chip 220 and the second lower conductive structures 312, thereby shielding the lower semiconductor chip 210 and the upper semiconductor chip 220 and the second lower conductive structures 312 from EMI. The first lower conductive structures 311 and the conductive layer 350 may prevent interference of electrical signals between the lower semiconductor chip 210 and the upper semiconductor chip 220 and other components of the semiconductor package 10. The other components may include second upper conductive structures 322 and upper redistribution patterns. Therefore, the operation reliability and the electrical characteristics of the semiconductor package 10 may be improved.

Since the first width W1 of the first lower conductive structures 311 is 50 μm or greater, the resistance of the first lower conductive structures 311 may be reduced. Therefore, a ground voltage may be more stably supplied to the conductive layer 350 through the first lower conductive structures 311. The EMI shielding characteristics of the first lower conductive structures 311 and the conductive layer 350 may be further improved.

The second upper conductive structures 322 may be arranged on the second lower conductive structures 312 and electrically connected to the second lower conductive structures 312, respectively. The second upper conductive structures 322 may include the same material as the material of the first lower conductive structures 311. The second upper conductive structures 322 may include copper, for example. The thicknesses of the second upper conductive structures 322 may be substantially identical to the thickness of the metal layer 351, but embodiments of the present disclosure are not limited thereto. The widths of the second upper conductive structures 322 may be greater than the widths of corresponding second lower conductive structures 312. Alternatively, the widths of the second upper conductive structures 322 may be equal to or smaller than the widths of corresponding second lower conductive structures 312.

In a comparative embodiment, when a single conductive structure is provided between the first substrate 100 and the second substrate 600, the height of the single conductive structure may be limited due to restrictions on the aspect ratio. According to embodiments, since the second lower conductive structures 312 and the second upper conductive structures 322 are provided, the sum of the heights of the first lower conductive structures 311 and the second upper conductive structures 322 may be relatively large. Accordingly, the restrictions on the gap between the first substrate 100 and the second substrate 600 are reduced, and thus the restrictions on the thickness of the lower semiconductor chip 210 and the thickness of the upper semiconductor chip 220 may be further reduced.

The semiconductor package 10 may further include upper seed patterns 325. The upper seed patterns 325 may be further provided on bottom surfaces of the second upper conductive structures 322, respectively. The upper seed patterns 325 may directly contact the top surfaces of the second lower conductive structures 312 and the bottom surfaces of the second upper conductive structures 322. The upper seed patterns 325 may include a material different from materials constituting the second lower conductive structures 312 and the second upper conductive structures 322. For example, the upper seed patterns 325 may include a conductive seed material. The thicknesses of the upper seed patterns 325 may be smaller than the thicknesses of the second upper conductive structures 322. The widths of the upper seed patterns 325 may be substantially identical to the widths of the second upper conductive structures 322. The thickness and the material of the upper seed patterns 325 may be substantially identical to the thickness and the material of the seed layer 355, but are not limited thereto.

According to embodiments, the upper seed patterns 325 may be omitted. In this case, the second upper conductive structures 322 may directly contact the top surfaces of the second lower conductive structures 312.

Referring to FIG. 1C together with FIG. 1B, grains 351G of the metal layer 351 may be different from grains 311G of the first lower conductive structures 311. For example, the size of the grains 351G of the metal layer 351 may be different from the size of the grains 311G of each of the first lower conductive structures 311. For example, the size of the grains 351G of the metal layer 351 may be greater than the size of the grains 311G of each of the first lower conductive structures 311. Alternatively, the shape of the grains 351G of the metal layer 351 may be different from the shape of the grains 311G of each of the first lower conductive structures 311, or the crystal structure of the grains 351G of the metal layer 351 may be different from the crystal structure of the grains 311G of the first lower conductive structures 311. In this specification, grain may refer to a grain boundary.

Grains 322G of the second upper conductive structures 322 may be different from grains 312G of the second lower conductive structures 312. For example, the size of the grains 322G of the second upper conductive structures 322 may be different from the size of the grains 312G of the second lower conductive structures 312. For example, the size of the grains 322G of the second upper conductive structures 322 may be greater than the size of the grains 312G of the second lower conductive structures 312. The shapes of the grains 351G of the metal layer 351, the grains 311G of the first lower conductive structures 311, the grains 312G of the second lower conductive structures 312, and the grains 322G of the second upper conductive structures 322 of FIG. 1B are schematic examples and may be modified in various ways.

Referring back to FIG. 1B, the insulation sealing film 430 may be disposed on the top surface of the molding film 400. The insulation sealing film 430 may cover the sidewalls 350c (refer to FIG. 1C) of the conductive layer 350, the sidewalls of the second upper conductive structures 322, and the top surface of the molding film 400. The insulation sealing film 430 may further cover the sidewalls of the upper seed patterns 325. The insulation sealing film 430 may include an insulation organic material such as an EMC or a photo-imageable dielectric (PID) material.

The second substrate 600 may be disposed on the conductive layer 350, the second upper conductive structures 322, and the molding film 400. For example, the second substrate 600 may be disposed on the insulation sealing film 430. The second substrate 600 may be electrically connected to the first substrate 100 through the second upper conductive structures 322 and the second lower conductive structures 312. For example, the second substrate 600 may be a second redistribution substrate. However, the type of the second substrate 600 and the components of the second substrate 600 may be modified in various ways. When the second substrate 600 is a second redistribution substrate, the second substrate 600 may include a second insulation layer 601, second redistribution patterns 630, second seed patterns 635, and second redistribution pads 650. For convenience, the case where the second substrate 600 is a second redistribution substrate is illustrated and described, but embodiments of the present disclosure are not limited thereto.

The second substrate 600 may include a plurality of second insulation layers 601. The plurality of second insulation layers 601 may be stacked on the conductive layer 350, the second upper conductive structures 322, and the insulation sealing film 430. The second insulation layers 601 may include a PID material. The PID material may be a polymer. The PID material may include, for example, at least one from among photosensitive polyimide, polybenzoxazole, phenol-based polymer, and benzocyclobutene-based polymer. For example, the second insulation layers 601 may include the same material as each other. The interface between second insulation layers 601 adjacent to each other may not be distinguished. The number of the second insulation layers 601 may vary.

The second redistribution patterns 630 may be provided in and on the second insulation layers 601. The lower portion of each of the second redistribution patterns 630 may be provided in a corresponding one of the second insulation layers 601. The width of the upper portion of each of the second redistribution patterns 630 may be greater than the width of the lower portion of each of the second redistribution patterns 630. The second redistribution patterns 630 may each extend onto the top surface of a corresponding one of the second insulation layers 601. The second redistribution patterns 630 may include a metal such as copper.

The second redistribution patterns 630 may include second lower redistribution patterns and second upper redistribution patterns stacked thereon. The second lower redistribution patterns may be arranged on the second upper conductive structures 322 and connected to the second upper conductive structures 322. The second upper redistribution patterns may be arranged on the second lower redistribution patterns and connected to the second lower redistribution patterns.

The second seed patterns 635 may be arranged on bottom surfaces of the second redistribution patterns 630, respectively. The second seed patterns 635 may include a material different from materials constituting the second upper conductive structures 322 and the second redistribution patterns 630. For example, the second seed patterns 635 may include a conductive seed material. The second seed patterns 635 may function as barrier layers to prevent diffusion of materials included in the second redistribution patterns 630.

The second redistribution pads 650 may each be disposed on a corresponding one of the second redistribution patterns 630 and connected to the corresponding one of the second redistribution patterns 630. For example, the second redistribution pads 650 may be arranged on the second upper redistribution patterns of the second redistribution pattern 630. The second redistribution pads 650 may be laterally spaced apart from each other. The lower portions of the second redistribution pads 650 may be provided within the uppermost one of the second insulation layers 601. The upper portions of the second redistribution pads 650 may extend onto the top surface of the uppermost one of the second insulation layers 601. For example, the second redistribution pads 650 may include metal, such as copper.

The second redistribution pads 650 may be connected to the second upper conductive structures 322 through the second redistribution patterns 630. Since the second redistribution patterns 630 are provided, at least one second redistribution pad 650 may not be vertically aligned with a second upper conductive structure 322 electrically connected to the at least one second redistribution pad 650. Therefore, the arrangement of the second redistribution pads 650 may be designed more freely. The number of second redistribution patterns 630 stacked between the second upper conductive structures 322 and the second redistribution pads 650 is not limited to the number shown in the drawings and may be modified in various ways.

Second seed pads 655 may be provided between the uppermost one of the second redistribution patterns 630 and the second redistribution pads 650. The second seed pads 655 may include a conductive seed material.

According to embodiments, the second redistribution patterns 630 may include ground redistribution patterns 630G. At least one ground redistribution pattern 630G may be provided on the conductive layer 350 and electrically connected to the conductive layer 350. The second redistribution pads 650 may include a ground redistribution pad 650G. The ground redistribution pad 650G may be disposed on the at least one ground redistribution pattern 630G and electrically connected to the at least one ground redistribution pattern 630G. The ground redistribution pad 650G may be exposed on the top surface of the second substrate 600. The ground redistribution pad 650G may vertically overlap the conductive layer 350. The ground redistribution pad 650G and the ground redistribution pattern 630G may receive a ground voltage through the conductive layer 350 and the first lower conductive structures 311. Therefore, the ground redistribution pad 650G may be configured to supply voltage to an upper package. Since the ground redistribution patterns 630G and the ground redistribution pad 650G are provided, the degree of freedom in designing the second redistribution patterns 630 may be increased.

Hereinafter, the first substrate 100 according to an embodiment will be described in more detail.

When the first substrate 100 is a redistribution substrate, the first substrate 100 may include the first insulation layer 101, the under bump patterns 120, the first redistribution patterns 130, the first seed patterns 135, the first seed pads 155, and the first redistribution pads 150 as described above. The first insulation layer 101 may include an organic material such as a PID material. For example, the plurality of first insulation layers 101 may include the same material as each other. The interface between first insulation layers 101 adjacent to each other may not be distinguished. The number of first insulation layers 101 that are stacked may vary.

The under bump patterns 120 may be provided in the lowermost one of the first insulation layers 101. The bottom surfaces of the under bump patterns 120 may not be covered by the lowermost one of the first insulation layers 101. The under bump patterns 120 may function as pads of solder ball terminals 550. The under bump patterns 120 may be laterally spaced apart from each other and may be electrically insulated from each other. The under bump patterns 120 may include a metal material such as copper.

First redistribution patterns 130 may be provided on the under bump patterns 120 and electrically connected to the under bump patterns 120. The first redistribution patterns 130 may include a metal such as copper. The lower portions of each of the first redistribution patterns 130 may be provided in a corresponding one of the first insulation layers 101. The width of the upper portion of each of the first redistribution patterns 130 may be greater than the width of the lower portion of each of the first redistribution patterns 130. The upper portion of each of the first redistribution patterns 130 may extend onto the top surface of a corresponding one of the first insulation layers 101.

The first redistribution patterns 130 may include first lower redistribution patterns and first upper redistribution patterns stacked thereon. The first lower redistribution patterns may be arranged on the under bump patterns 120. The first upper redistribution patterns may be disposed on the first lower redistribution patterns and connected to the first lower redistribution patterns.

The first seed patterns 135 may be arranged on bottom surfaces of the first redistribution patterns 130, respectively. The first seed patterns 135 may include a material different from materials constituting the under bump patterns 120 and the first redistribution patterns 130. For example, the first seed patterns 135 may include a conductive seed material.

The first redistribution pads 150 may be provided in an uppermost one of the first insulation layers 101 and extend onto the top surface of the uppermost one of the first insulation layers 101. The lower portions of the first redistribution pads 150 may be arranged within the uppermost one of the first insulation layers 101. The upper portions of the first redistribution pads 150 may be arranged on the top surface of the uppermost one of the first insulation layers 101. The upper portion of each of the first redistribution pads 150 may have a width greater than that of the lower portion of each of the first redistribution pads 150 and may be connected to the lower portion of each of the first redistribution pads 150. The first redistribution pads 150 may be laterally spaced apart from each other. The first redistribution pads 150 may be arranged on the first redistribution patterns 130. The first redistribution pads 150 may be connected to the under bump patterns 120 through the first redistribution patterns 130. Since the first redistribution patterns 130 are provided, any one first redistribution pad 150 may not be vertically aligned with an under bump pattern 120 that is electrically connected to the any one first redistribution pad 150. Therefore, the arrangement of the first redistribution pads 150 may be designed more freely. The number of first redistribution patterns 130 stacked between the under bump patterns 120 and the first redistribution pads 150 is not limited to the number shown in the drawings and may be modified in various ways.

The first seed pads 155 may be provided on the bottom surfaces of the first redistribution pads 150, respectively. The first seed pads 155 may be provided between the first upper redistribution patterns and the first redistribution pads 150, and the first redistribution patterns 130 may extend between the uppermost one of the first insulation layers 101 and the first redistribution pads 150. The first seed pads 155 may include a material different from a material constituting the first redistribution pads 150. The first seed pads 155 may include, for example, a conductive seed material.

FIG. 1D is a diagram illustrating a semiconductor package according to embodiments, corresponding to a cross-section taken along a line I-I′ of FIG. 1A.

Referring to FIG. 1D, a semiconductor package 10A may be a lower package. The semiconductor package 10A may include the first substrate 100, the solder ball terminals 500, the lower semiconductor chip 210, the upper semiconductor chip 220, the first lower conductive structures 311, the second lower conductive structures 312, the second upper conductive structure 322, the lower solder bumps 510, the first upper solder bumps 520, the molding film 400, the insulation sealing film 430, and the second substrate 600, as described with reference to the embodiment of FIGS. 1A to 1C. For example, the second substrate 600 may be a second redistribution substrate. The second substrate 600 may include the second insulation layer 601, the second redistribution patterns 630, the second seed patterns 635, and the second redistribution pads 650. However, the second substrate 600 may not be electrically connected to the conductive layer 350. For example, the second redistribution patterns 630 may not include the ground redistribution patterns 630G described with reference to the embodiment of FIG. 1B. The second redistribution pads 650 may not include the ground redistribution pad 650G described with reference to the embodiment of FIG. 1B. The second redistribution patterns 630 and the second redistribution pads 650 may be spaced apart and electrically separated from the conductive layer 350.

The first lower conductive structures 311 and the conductive layer 350 may be configured to receive a ground voltage. The first lower conductive structures 311 and the conductive layer 350 may shield EMI from the lower semiconductor chip 210 and the upper semiconductor chip 220.

FIG. 1E is a plan view of a semiconductor package according to embodiments. A cross-section taken along a line I-I′ of FIG. 1E is the same as the cross-section shown in FIG. 1B or 1D.

Referring to FIGS. 1E and 1B, a semiconductor package 10B may include the first substrate 100, the solder ball terminals 500, the lower semiconductor chip 210, the upper semiconductor chip 220, the first lower conductive structure 311, the second lower conductive structures 312, and the second upper conductive structures 322, as described with reference to the embodiment of FIGS. 1A and 1B. Although not shown in FIG. 1E, the semiconductor package 10B may further include the lower solder bumps 510, the first upper solder bumps 520, the molding film 400, the insulation sealing film 430, and the second substrate 600, as described with reference to the embodiment of FIG. 1B or 1D.

However, the semiconductor package 10B may include a single first lower conductive structure 311. The first lower conductive structure 311 may be a first lower partition wall structure. For example, the first lower conductive structure 311 may surround the lower semiconductor chip 210 in a plan view. Inner surfaces 311c of the first lower conductive structure 311 may face the lower semiconductor chip 210 and be spaced apart from the lower semiconductor chip 210. The inner surfaces 311c of the first lower conductive structure 311 may have a rectangular shape. Outer surfaces 311d of the first lower conductive structure 311 may face away from the inner surfaces 311c. The outer surfaces 311d of the first lower conductive structure 311 may have a rectangular shape.

FIG. 1F is a diagram illustrating a semiconductor package according to embodiments, corresponding to a cross-section taken along a line I-I′ of FIG. 1A or FIG. 1E.

Referring to FIG. 1F, a semiconductor package 10C may include the first substrate 100, the solder ball terminals 500, the lower semiconductor chip 210, the upper semiconductor chip 220, the first lower conductive structures 311, the second lower conductive structures 312, the second upper conductive structure 322, the lower solder bumps 510, the first upper solder bumps 520, the molding film 400, the insulation sealing film 430, and the second substrate 600, as described with reference to the embodiment of FIGS. 1A and 1B.

The conductive layer 350 may include the seed layer 355 and the metal layer 351. The seed layer 355 may be provided on the bottom surface and the sidewalls of the conductive layer 350. The seed layer 355 may be provided between the conductive layer 350 and the insulation sealing film 430. The topmost surface of the seed layer 355 may be coplanar with the top surface of the conductive layer 350 and the top surface of the insulation sealing film 430. For example, the topmost surface of the seed layer 355 may be provided at a level substantially identical to a level of the top surface of the conductive layer 350. Sidewalls 350c of the conductive layer 350 may correspond to sidewalls of the seed layer 355.

The upper seed patterns 325 may cover the bottom surfaces and the sidewalls of the second upper conductive structures 322. The upper seed patterns 325 may extend between the sidewalls of the second upper conductive structures 322 and the insulation sealing film 430. The topmost surfaces of the upper seed patterns 325 may be coplanar with the top surfaces of the second upper conductive structures 322.

FIG. 1G is a diagram illustrating a semiconductor package according to embodiments, corresponding to a cross-section taken along a line I-I′ of FIG. 1A or FIG. 1E.

Referring to FIG. 1G, a semiconductor package 10D may include the first substrate 100, the solder ball terminals 500, the lower semiconductor chip 210, the upper semiconductor chip 220, the first lower conductive structures 311, the second lower conductive structures 312, the second upper conductive structure 322, the lower solder bumps 510, the first upper solder bumps 520, the molding film 400, the insulation sealing film 430, and the second substrate 600, as described with reference to the embodiment of FIGS. 1A and 1B.

However, the insulation sealing film 430 may include a first insulation sealing film 431 and a second insulation sealing film 432. The first insulation sealing film 431 may be disposed on the molding film 400 and cover the top surface of the molding film 400. The first insulation sealing film 431 may include, for example, a photosensitive polymer. The second insulation sealing film 432 may be disposed on the first insulation sealing film 431. The second insulation sealing film 432 may include an insulation material different from an insulating material constituting the first insulation sealing film 431. For example, the second insulation sealing film 432 may include an EMC. In another example, the second insulation sealing film 432 may include a PID material. When the first insulation sealing film 431 and the second insulation sealing film 432 include a PID material, the interface between the first insulation sealing film 431 and the second insulation sealing film 432 may not be distinguished.

The conductive layer 350 may include a seed layer 355 and a metal layer 351. The lower portion of the metal layer 351 may be disposed within the first insulation sealing film 431. The upper portion of the metal layer 351 may be disposed within the second insulation sealing film 432. The width of the upper portion of the metal layer 351 may be greater than the width of the lower portion of the metal layer 351. The lower portion of the metal layer 351 may have inclined sidewalls. The seed layer 355 may cover the bottom surface of the metal layer 351 and extend between the metal layer 351 and the first insulation sealing film 431. For example, the seed layer 355 may be provided between the lower portion of the metal layer 351 and the first insulation sealing film 431 and between the upper portion of the metal layer 351 and the first insulation sealing film 431. The sidewalls of the upper portion of the metal layer 351 may be in direct physical contact with the second insulation sealing film 432.

The lower portions of the second upper conductive structures 322 may be arranged within the first insulation sealing film 431. The upper portions of the second upper conductive structures 322 may be arranged within the second insulation sealing film 432. The width of each of the upper portions of the second upper conductive structures 322 may be greater than the width of each of the lower portions of the second upper conductive structures 322. The lower portions of the second upper conductive structures 322 may have inclined sidewalls.

The upper seed patterns 325 may cover the bottom surfaces of the second upper conductive structures 322 and extend between the second upper conductive structures 322 and the first insulation sealing film 431. The sidewalls of the upper portions of the second upper conductive structures 322 may be in direct physical contact with the second insulation sealing film 432.

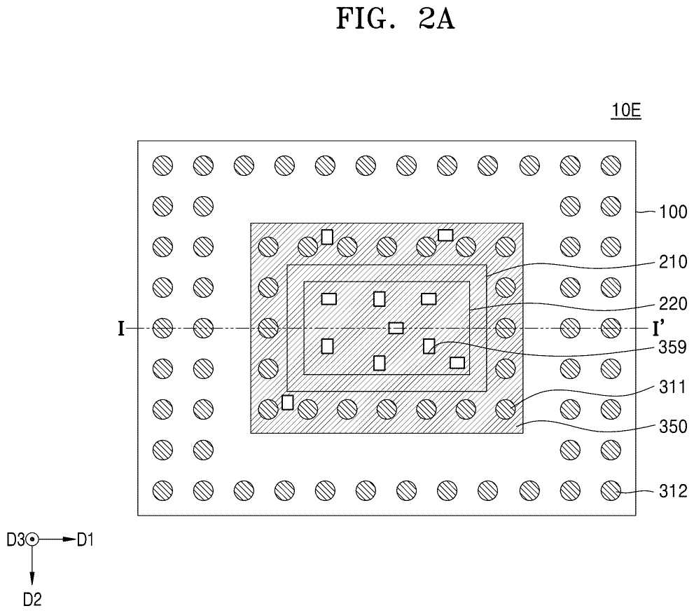

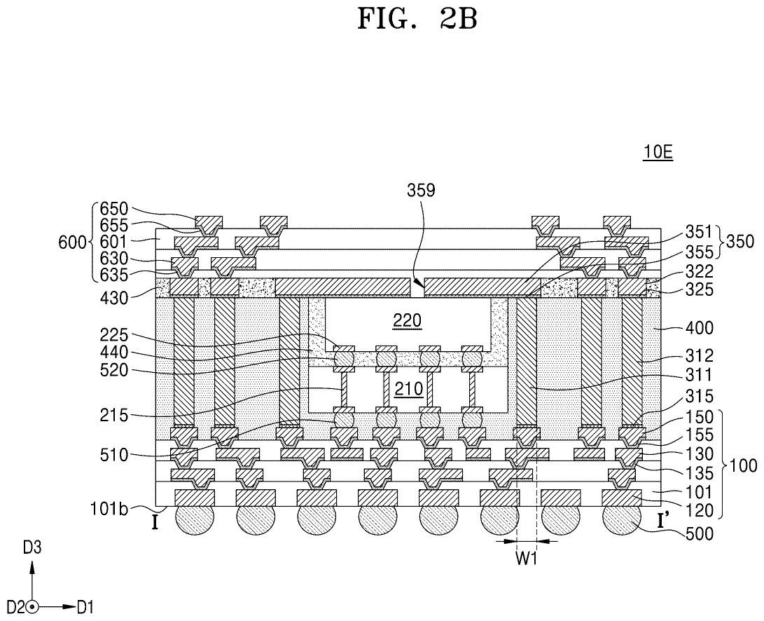

FIG. 2A is a plan view of a semiconductor package according to embodiments. FIG. 2B is a cross-sectional view taken along a line I-I′ of FIG. 2A.

Referring to FIGS. 2A and 2B, a semiconductor package 10E may include the first substrate 100, the solder ball terminals 500, the lower semiconductor chip 210, the upper semiconductor chip 220, the first lower conductive structures 311, the second lower conductive structures 312, the second upper conductive structure 322, the lower solder bumps 510, the first upper solder bumps 520, the molding film 400, the insulation sealing film 430, and the second substrate 600, as described with reference to the embodiment of FIGS. 1A and 1B. The semiconductor package 10 may be a lower package.

The conductive layer 350 may be disposed on the upper semiconductor chip 220 and the first lower conductive structures 311 and contact the top surfaces of the first lower conductive structures 311. The conductive layer 350 may have a plurality of holes 359. The holes 359 may penetrate through the top surface and the bottom surface of the conductive layer 350. The holes 359 may expose the top surface of the upper semiconductor chip 220. Even when the holes 359 are provided, the conductive layer 350 may still contact from about 20% to about 100% of the top surface of the upper semiconductor chip 220.

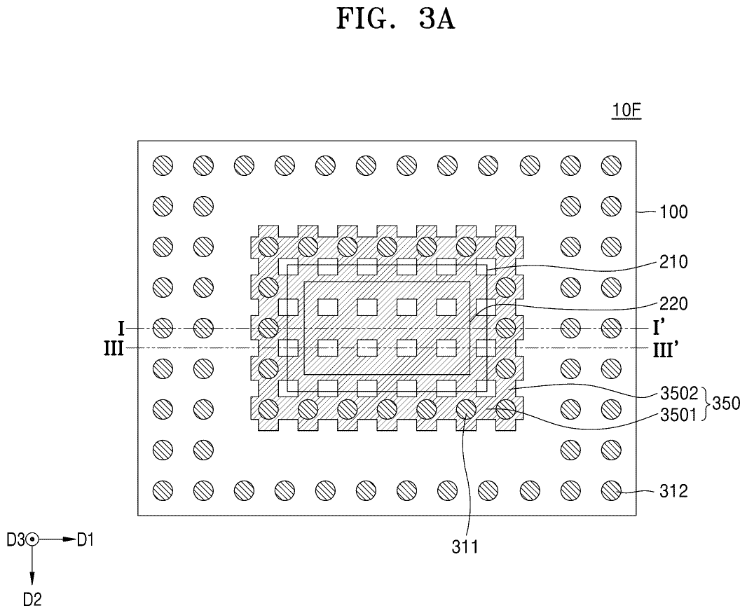

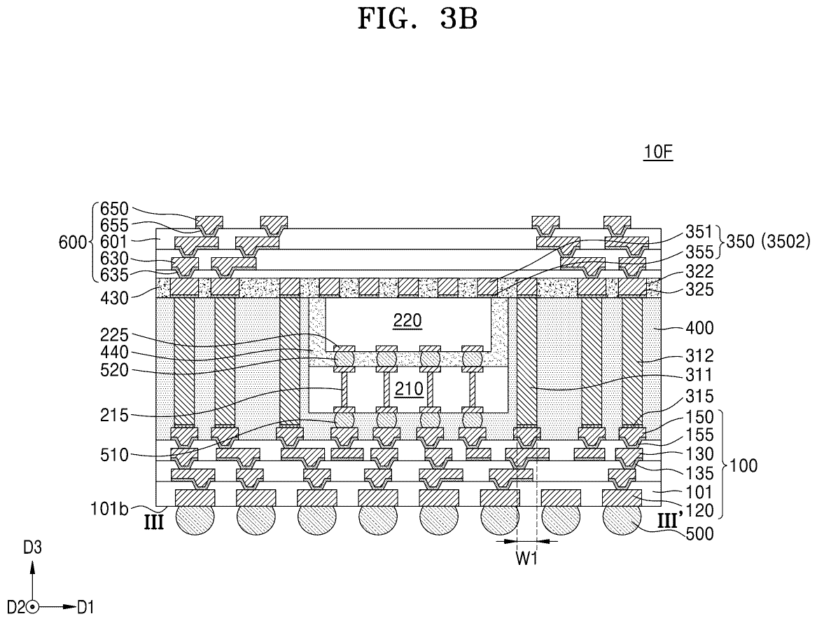

FIG. 3A is a plan view of a semiconductor package according to embodiments. FIG. 3B is a cross-sectional view taken along a line III-III′ of FIG. 3A. A cross-section taken along a line I-I′ of FIG. 3A may be the same cross-section as shown in FIG. 1B.

Referring to FIGS. 3A and 3B together with FIG. 1B, a semiconductor package 10F may be a lower package. The semiconductor package 10F may include the first substrate 100, the solder ball terminals 500, the lower semiconductor chip 210, the upper semiconductor chip 220, the first lower conductive structures 311, the second lower conductive structures 312, the second upper conductive structure 322, the lower solder bumps 510, the first upper solder bumps 520, the molding film 400, the insulation sealing film 430, and the second substrate 600, as described with reference to the embodiment of FIGS. 1A and 1B.

The conductive layer 350 may include first portions 3501 and second portions 3502. The conductive layer 350 may have a grid-like shape in a plan view. For example, the first portions 3501 of the conductive layer 350 may extend in parallel to the first direction D1 in a plan view. The first portions 3501 of the conductive layer 350 may be spaced apart from each other in the second direction D2. The second portions 3502 of the conductive layer 350 may extend in parallel to the second direction D2 in a plan view. The second portions 3502 of the conductive layer 350 may be connected to the first portions 3501. The second portions 3502 of the conductive layer 350 may be spaced apart from each other in the first direction D1. The conductive layer 350 may expose at least a portion of the top surface of the upper semiconductor chip 220. The conductive layer 350 may physically contact from about 20% to about 100% of the planar area of the top surface of the upper semiconductor chip 220.

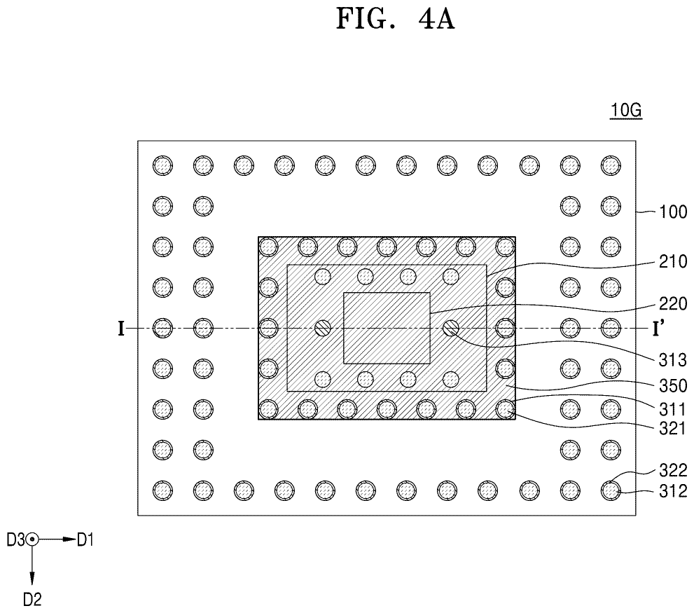

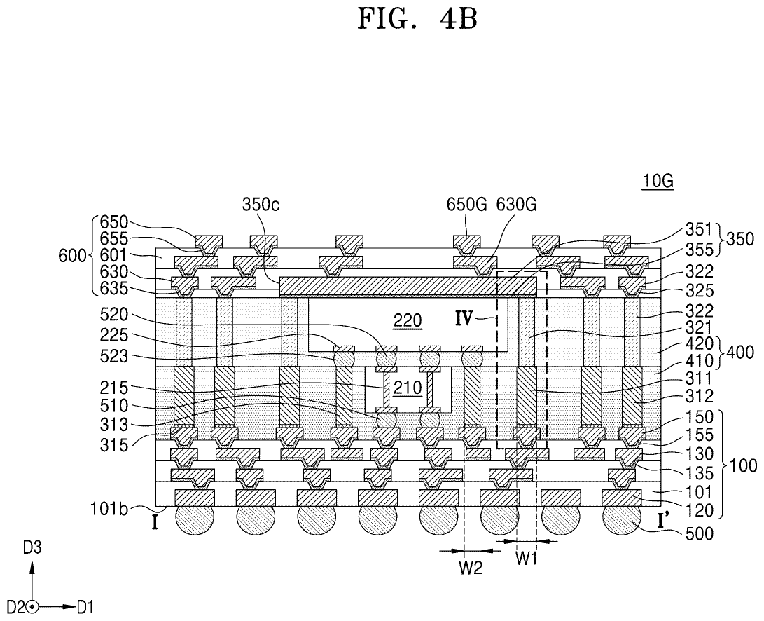

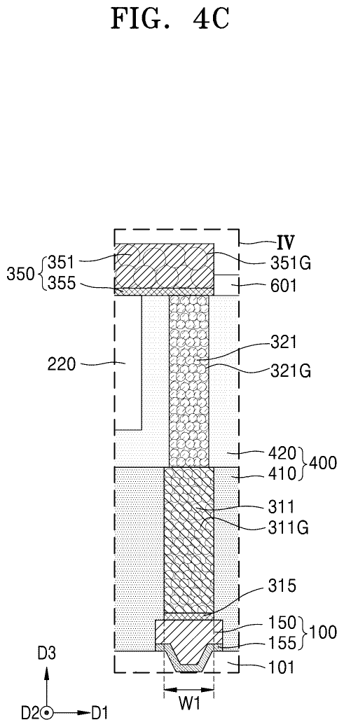

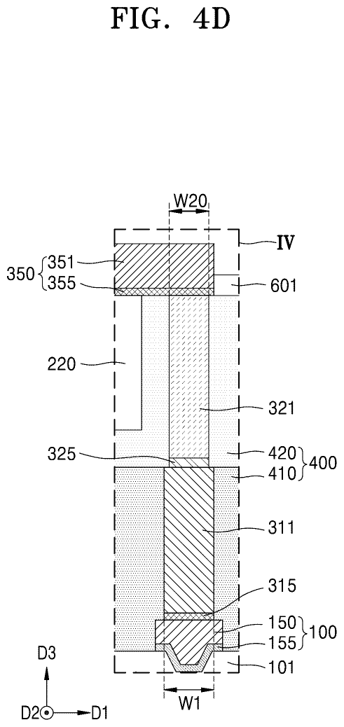

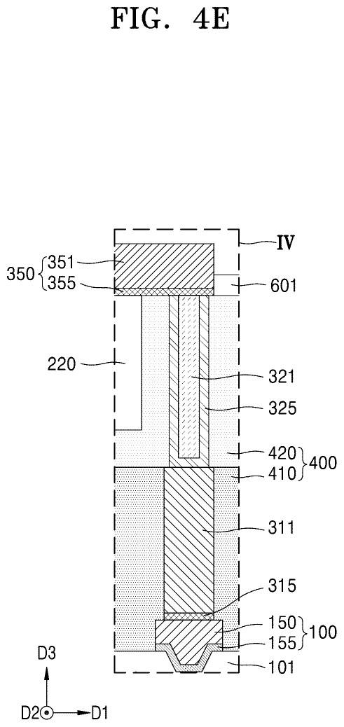

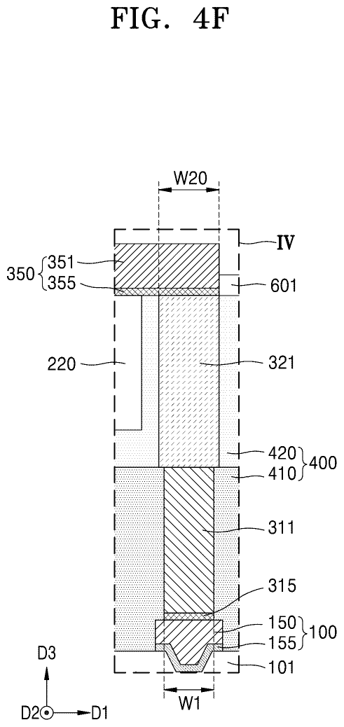

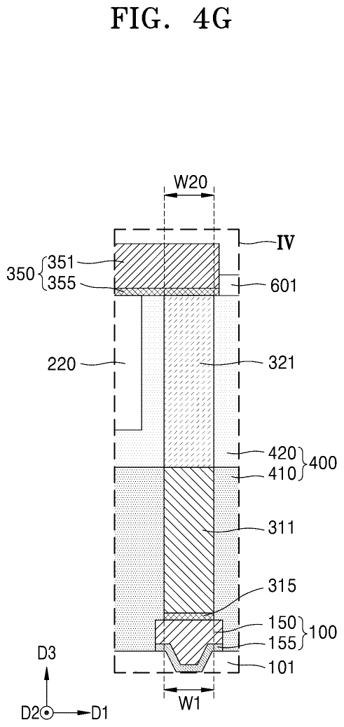

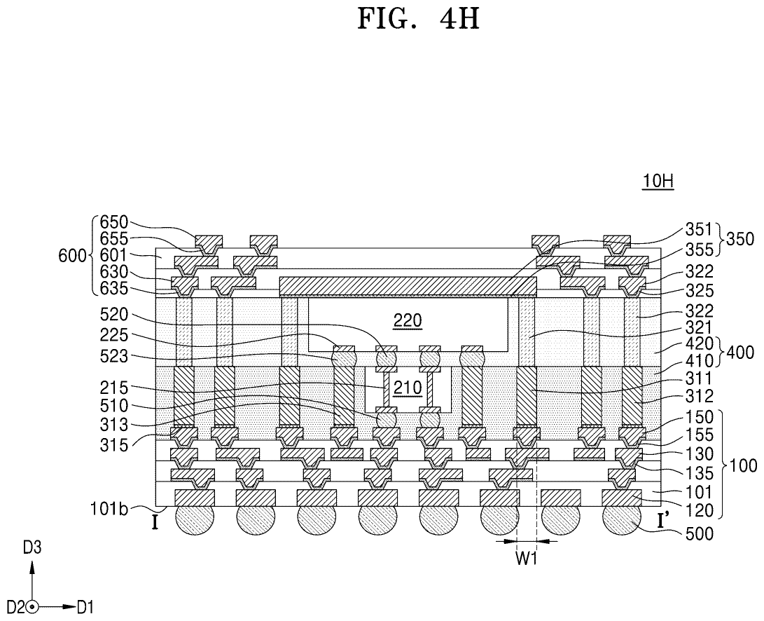

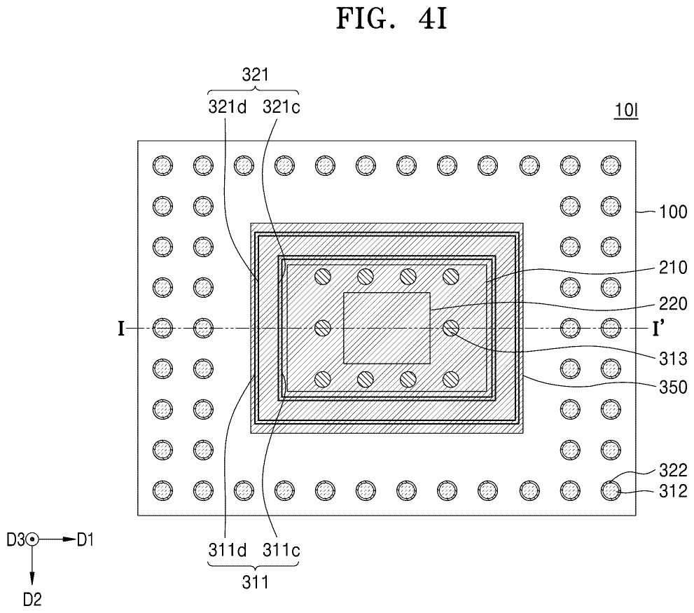

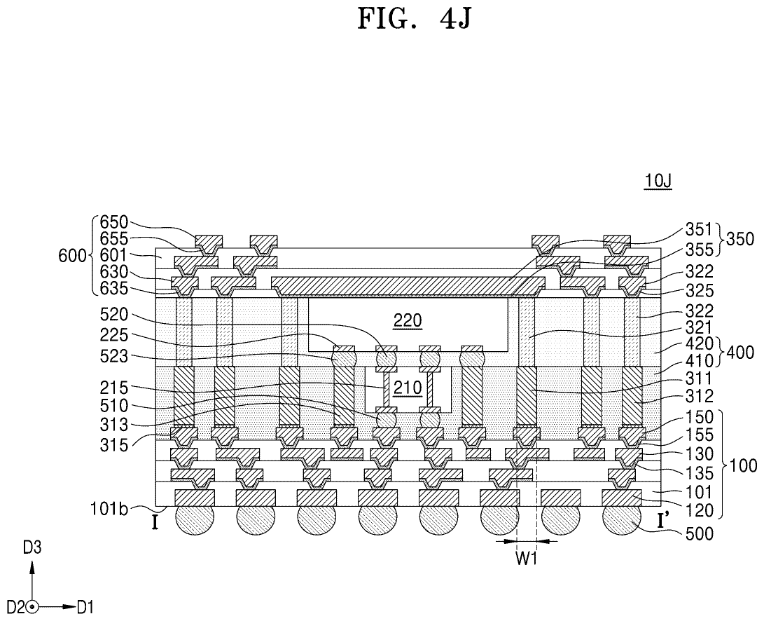

FIG. 4A is a plan view of a semiconductor package according to embodiments. FIG. 4B is a cross-sectional view taken along a line I-I′ of FIG. 4A. FIG. 4C is an enlarged view of a region IV of FIG. 4B. Hereinafter, descriptions identical to descriptions already given above may not be repeated.

Referring to FIGS. 4A to 4C, a semiconductor package 10G may be a lower package. The semiconductor package 10G may include the first substrate 100, solder ball terminals 500, the lower semiconductor chip 210, the upper semiconductor chip 220, the first lower conductive structures 311, the second lower conductive structures 312, the second upper conductive structure 322, the lower solder bumps 510, the first upper solder bumps 520, the molding film 400, the insulation sealing film 430, and the second substrate 600. However, the semiconductor package 10G may not include the internal molding film 440 as described with reference to the embodiment of FIGS. 1A and 1B.

The semiconductor package 10G may further include third lower conductive structures 313. The third lower conductive structures 313 may be provided on the top surface of the first substrate 100 and laterally spaced apart from the lower semiconductor chip 210. The third lower conductive structures 313 may be arranged on corresponding ones of the first redistribution pads 150, respectively. The lower seed patterns 315 may be further provided between the third lower conductive structures 313 and the first redistribution pads 150. The third lower conductive structures 313 may receive voltage through the first substrate 100 and the solder ball terminals 500. The voltage may be a power voltage. The power voltage may be different from the ground voltage. A width W2 of each of the third lower conductive structures 313 may be smaller than the first width W1. The width W2 of each of the third lower conductive structures 313 may be greater than the width of each of the through vias 215.

The upper semiconductor chip 220 may be disposed on the lower semiconductor chip 210 and the third lower conductive structures 313. The width of the upper semiconductor chip 220 may be greater than the width of the lower semiconductor chip 210. The upper semiconductor chip 220 may be electrically connected to the lower semiconductor chip 210 through first upper solder bumps 520.

The semiconductor package 10G may further include second upper solder bumps 523. The second upper solder bumps 523 may be provided between the third lower conductive structures 313 and the upper semiconductor chip 220 and connected to the third lower conductive structures 313 and corresponding ones of the chip pads 225 of the upper semiconductor chip 220. The second upper solder bumps 523 may include solder balls. According to embodiments, the second upper solder bumps 523 may further include pillar patterns. The size of each of the second upper solder bumps 523 may be larger than the size of each of the first upper solder bumps 520. For example, the width of each of the second upper solder bumps 523 may be larger than the width of each of the first upper solder bumps 520.

The molding film 400 may include a lower molding film 410 and an upper molding film 420. The lower molding film 410 may be disposed on the top surface of the first substrate 100 and cover the sidewalls of the lower semiconductor chip 210 and the sidewalls of first lower conductive structures 311, second lower conductive structures 312, and third lower conductive structures 313. The lower molding film 410 may extend to the first gap region between the first substrate 100 and the lower semiconductor chip 210 and cover the sidewalls of the lower solder bumps 510. The top surface of the lower molding film 410 may be coplanar with the top surface of the lower semiconductor chip 210 and the top surfaces of the first lower conductive structures 311, the second lower conductive structures 312, and the third conductive structures 313. The lower molding film 410 may include an EMC.

The semiconductor package 10G may further include first upper conductive structures 321. The first upper conductive structures 321 may be arranged on the top surfaces of the first lower conductive structures 311. For example, the first upper conductive structures 321 may directly contact the top surfaces of the first lower conductive structures 311 as shown in FIG. 1B, but embodiments of the present disclosure are not limited thereto. The first upper conductive structures 321 may be laterally spaced apart from the upper semiconductor chip 220. For example, the first upper conductive structures 321 may be arranged between the upper semiconductor chip 220 and the second upper conductive structures 322. The first upper conductive structures 321 may include metal posts each having a cylindrical shape. The first upper conductive structures 321 may surround the upper semiconductor chip 220 in a plan view. For example, the first upper conductive structures 321 may be arranged between four side surfaces of the upper semiconductor chip 220 and the side surfaces of the first substrate 100 in a plan view. The planar arrangement of the first upper conductive structures 321 may correspond to the planar arrangement of the first lower conductive structures 311. As shown in FIG. 4B, any one of the first upper conductive structures 321 may be disposed on a first side of the upper semiconductor chip 220, and another one of the first upper conductive structures 321 may be disposed on a second side of the upper semiconductor chip 220. The second side of the upper semiconductor chip 220 may face away from the first side of the upper semiconductor chip 220.

The upper molding film 420 may be disposed on the top surface of the lower molding film 410. The upper molding film 420 may cover the sidewalls of the upper semiconductor chip 220 and the sidewalls of the first upper conductive structures 321 and the second upper conductive structures 322. The upper molding film 420 may further cover the sidewalls of the second upper solder bumps 523. The upper molding film 420 may further extend into a second gap region between the lower semiconductor chip 210 and the upper semiconductor chip 220 and further cover the sidewalls of the first upper solder bumps 520. The top surface of the upper molding film 420 may be coplanar with the top surface of the upper semiconductor chip 220 and the top surfaces of the first upper conductive structures 321 and the second upper conductive structures 322. The upper molding film 420 may include an EMC.

The conductive layer 350 may be disposed on the upper semiconductor chip 220, the second upper conductive structures 322, and the upper molding film 420 and electrically connected to the second upper conductive structures 322. The conductive layer 350 may include the seed layer 355 and the metal layer 351. The seed layer 355 may be in direct physical contact with the top surface of the upper semiconductor chip 220 and the top surfaces of the second upper conductive structures 322. The seed layer 355 may physically contact a portion of the top surface of the upper molding film 420. A ground voltage may be applied to the first lower conductive structures 311, the first upper conductive structures 321, and the conductive layer 350 through the solder ball terminals 500 and the first substrate 100.

The second substrate 600 may be disposed on the upper molding film 420. At least one second insulation layer 601 may cover the sidewalls of the conductive layer 350. The plurality of ground redistribution patterns 630G and a plurality of ground redistribution pads 650G may be provided on the conductive layer 350 and electrically connected to the conductive layer 350. The number of ground redistribution patterns 630G and the number of ground redistribution pads 650G may vary.

Referring to FIG. 4C together with FIG. 4B, the grains 351G of the metal layer 351 may be different from the grains 311G of the first lower conductive structures 311 and grains 321G of the first upper conductive structures 321. For example, the size of the grains 351G of the metal layer 351 may be different from the size of the grains 311G of the first lower conductive structures 311 and the size of the grains 321G of the first upper conductive structures 321. For example, the size of the grains 351G of the metal layer 351 may be larger than the size of the grains 311G of the first lower conductive structures 311. The size of the grains 351G of the metal layer 351 may be larger than the size of the grains 321G of the first upper conductive structures 321. Alternatively, the shape of the grains 351G of the metal layer 351 may be different from the shape of the grains 311G of the first lower conductive structures 311 and the shape of the grains 321G of the first upper conductive structures 321. The shapes of the grains 351G of the metal layer 351, the grains 311G of the first lower conductive structures 311, and the grains 321G of the first upper conductive structures 321 in FIG. 4C are schematic examples and may be modified in various ways.

Grains of the second redistribution patterns 630 may be different from the grains 312G of the second lower conductive structures 312 and the grains 322G of the second upper conductive structures 322. The size of the grains of the second redistribution patterns 630 may be larger than the size of the grains of the second lower conductive structures 312 and the size of the grains of the second upper conductive structures 322.

FIG. 4D is a diagram illustrating a first upper conductive structure according to embodiments, and is an enlarged view of the region IV of FIG. 4B. Hereinafter, a single first upper conductive structure and a single first lower conductive structure will be described.

Referring to FIG. 4D together with FIG. 4B, the semiconductor package 10G of FIG. 4B may further include an upper seed pattern 325. The upper seed pattern 325 may be disposed on the bottom surface of a first upper conductive structure 321. The width of the upper seed pattern 325 on the bottom surface of the first upper conductive structure 321 may be substantially identical to the width of the first upper conductive structure 321. The upper molding film 420 may directly contact the sidewalls of the upper seed pattern 325 and the sidewalls of the first upper conductive structure 321.

The upper seed pattern 325 may be provided in plural and may correspond to a plurality of the first upper conductive structure 321, respectively. According to embodiments, some of the plurality of upper seed patterns 325 may be further provided on the bottom surfaces of the second upper conductive structures 322 of FIG. 4B.

FIG. 4E is a diagram illustrating a first upper conductive structure according to embodiments, and is an enlarged view of the region IV of FIG. 4B.

Referring to FIG. 4E together with FIG. 4B, the semiconductor package 10G of FIG. 4B may further include an upper seed pattern 325. The upper seed pattern 325 may cover the bottom surface and the sidewalls of the first upper conductive structure 321. The upper molding film 420 may directly contact the sidewalls of the upper seed pattern 325 and spaced apart from the first upper conductive structure 321. The conductive layer 350 may further contact the topmost surface of the upper seed pattern 325.

The upper seed pattern 325 may be provided in plural and correspond to a plurality of the first upper conductive structures 321, respectively. According to embodiments, some of the plurality of upper seed patterns 325 may be further provided on the bottom surfaces and the sidewalls of the second upper conductive structures 322 of FIG. 4B.

FIG. 4F is a diagram illustrating a first upper conductive structure according to embodiments, and is an enlarged view of the region IV of FIG. 4B.

Referring to FIG. 4F together with FIG. 4B, a width W20 of the first upper conductive structure 321 may be greater than the first width W1. In this case, the width of the second upper conductive structure 322 of FIG. 4B may be greater than the width of a second lower conductive structure 312.

FIG. 4G is a diagram illustrating a first upper conductive structure according to embodiments, and is an enlarged view of the region IV of FIG. 4B.

Referring to FIG. 4F together with FIG. 4B, the width W20 of the first upper conductive structure 321 may be substantially identical to the first width W1. The width of the second upper conductive structure 322 of FIG. 4B may be substantially identical to the width of the second lower conductive structure 312.

FIG. 4H is a diagram illustrating a semiconductor package according to embodiments, corresponding to a cross-section taken along a line I-I′ of FIG. 4A.

Referring to FIG. 4H, a semiconductor package 10H may include the first substrate 100, the solder ball terminals 500, the lower semiconductor chip 210, the upper semiconductor chip 220, the first lower conductive structures 311, the first upper conductive structure 321, the second lower conductive structures 312, the second upper conductive structure 322, the third lower conductive structures 313, the lower solder bumps 510, the first upper solder bumps 520, the second upper solder bumps 523, the molding film 400, and the second substrate 600, as described with reference to the embodiment of FIGS. 4A to 4C.

For example, the second substrate 600 may include the second insulation layer 601, the second redistribution patterns 630, the second seed patterns 635, and the second redistribution pads 650. However, the second substrate 600 may not be electrically connected to the conductive layer 350. For example, the second redistribution patterns 630 may not include the ground redistribution patterns 630G described with reference to the embodiment of FIG. 4B. The second redistribution pads 650 may not include the ground redistribution pads 650G described with reference to the embodiment of FIG. 4B. The second redistribution patterns and the second redistribution pads may be spaced apart and electrically separated from the conductive layer 350.

The first lower conductive structures 311, the first upper conductive structures 321, and the conductive layer 350 may be configured to receive a ground voltage. The first lower conductive structures 311, first upper conductive structures 321, and conductive layer 350 may shield EMI of the lower semiconductor chip 210 and the upper semiconductor chip 220.

FIG. 4I is a plan view of a semiconductor package according to embodiments. A cross-section taken along a line I-I′ of FIG. 4I is the same cross-section as shown in FIG. 4B or 4H.

Referring to FIGS. 4I and 4B, a semiconductor package 10I may be substantially identical to the semiconductor package described with reference to the embodiment of FIGS. 4A and 4B. However, the semiconductor package 10I may include a single first lower conductive structure 311 and a single first upper conductive structure 321. The first lower conductive structure 311 may be a first lower partition wall structure. For example, the first lower conductive structure 311 may surround the lower semiconductor chip 210 in a plan view. The inner surfaces 311c of the first lower conductive structure 311 may face the lower semiconductor chip 210 and be spaced apart from the lower semiconductor chip 210. The inner surfaces 311c of the first lower conductive structure 311 may have a rectangular shape. Outer surfaces 311d of the first lower conductive structure 311 may face away from the inner surfaces 311c. The outer surfaces 311d of the first lower conductive structure 311 may have a rectangular shape.

The first upper conductive structure 321 may be a first upper partition wall structure. For example, the first upper conductive structures 321 may surround the upper semiconductor chip 220 in a plan view. The inner surfaces 321c of the first upper conductive structure 321 may face the upper semiconductor chip 220 and be spaced apart from the upper semiconductor chip 220. The inner surfaces 321c of the first upper conductive structure 321 may have a rectangular shape. Outer surfaces 321d of the first upper conductive structure 321 may face away from the inner surfaces 321c. The outer surfaces 321d of the first upper conductive structure 321 may have a rectangular shape.

FIG. 4J is a diagram illustrating a semiconductor package according to embodiments, corresponding to a cross-section taken along a line I-I′ of FIG. 4A or FIG. 4I.

Referring to FIG. 4J, a semiconductor package 10J may be substantially identical to the semiconductor package described with reference to the embodiments of FIGS. 4A to 4I. For example, the conductive layer 350 may include the seed layer 355 and the metal layer 351. However, the lower portion of the metal layer 351 may be disposed within the lowermost one of the second insulation layers 601. The lower portion of the metal layer 351 may have inclined sidewalls. The upper portion of the metal layer 351 may be disposed on the lower portion of the metal layer 351 and extend onto the top surface of the lowermost one of the second insulation layer 601. The width of the upper portion of the metal layer 351 may be greater than the width of the lower portion of the metal layer 351. The seed layer 355 may cover the bottom surface of the metal layer 351 and extend between the metal layer 351 and the lowermost one of the second insulation layers 601. For example, the seed layer 355 may be provided between the lower portion of the metal layer 351 and the lowermost one of the second insulation layer 601 and between the upper portion of the metal layer 351 and the lowermost one of the second insulation layer 601. The sidewalls of the upper portion of the metal layer 351 may be in direct contact with any one of the second insulation layers 601.

Embodiments of the present disclosure may be combined with each other. For example, at least two embodiments from among the embodiment of FIGS. 1A to 1C, the embodiment of FIG. 1D, the embodiment of FIG. 1E, the embodiment of FIG. 1F, the embodiment of FIG. 1G, the embodiment of FIGS. 2A and 2B, the embodiment of FIGS. 3A and 3B, the embodiment of FIGS. 4A to 4C, the embodiment of FIG. 4D, the embodiment of FIG. 4E, the embodiment of FIG. 4F, the embodiment of FIG. 4G, the embodiment of FIG. 4I, and embodiment of FIG. 4J may be combined with each other.

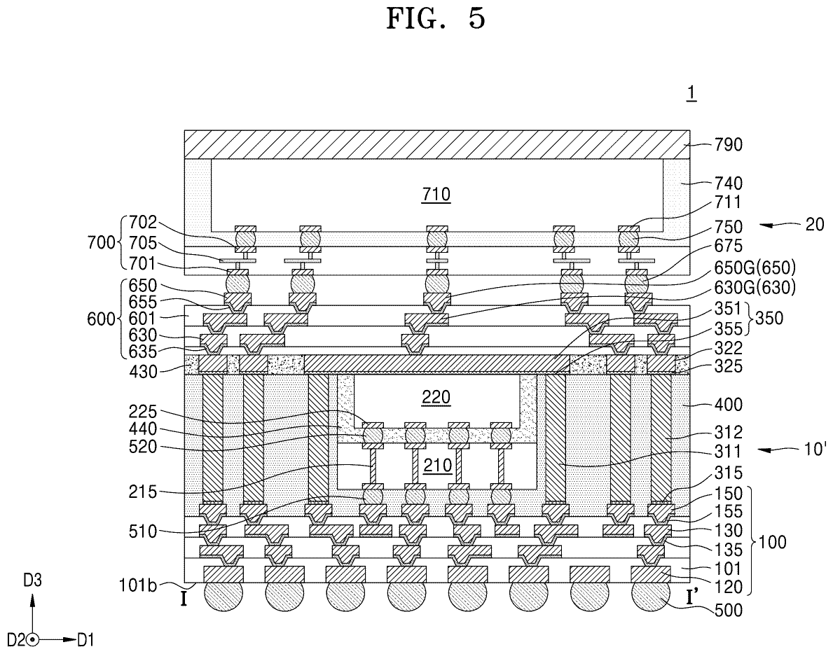

FIG. 5 is a diagram illustrating a semiconductor package according to embodiments.

Referring to FIG. 5, a semiconductor package 1 may include a lower package 10′ and an upper package 20. The lower package 10′ may be substantially identical to the semiconductor package 10 described with reference to the embodiment of FIGS. 1A and 1B. For example, the lower package 10′ may include the first substrate 100, solder ball terminals 500, the lower semiconductor chip 210, the upper semiconductor chip 220, the first lower conductive structure 311, the second lower conductive structures 312, the second upper conductive structure 322, the lower solder bumps 510, the first upper solder bumps 520, the molding film 400, the insulation sealing film 430, and the second substrate 600.

In another example, the lower package 10′ may be substantially identical to the semiconductor package 10A of FIG. 1D, the semiconductor package 10B of FIG. 1E, the semiconductor package 10C of FIG. 1F, the semiconductor package 10D of FIG. 1G, the semiconductor package 10E of FIG. 2A and FIG. 2B, the semiconductor package 10E, semiconductor package 10F of FIGS. 3A and 3B, the semiconductor package 10G of FIGS. 4A and 4B, the semiconductor package 10H of FIG. 4H, the semiconductor package 10I of FIG. 4I, or the semiconductor package 10J of FIG. 4J.

The upper package 20 may include an upper substrate 700, a semiconductor element 710, and a molding pattern 740. The upper substrate 700 is disposed on the top surface of the second substrate 600 and may be spaced apart from the top surface of the second substrate 600. The upper substrate 700 may be a printed circuit board (PCB) or a redistribution layer. First substrate pads 701 and second substrate pads 702 may be arranged at the bottom surface and the top surface of the upper substrate 700, respectively. Metal wires 705 may be provided in the upper substrate 700 and connected to the first substrate pads 701 and the second substrate pads 702.

The semiconductor element 710 may be mounted on the top surface of the upper substrate 700. The semiconductor element 710 may include a semiconductor chip such as a memory chip or a logic chip. The semiconductor element 710 may have chip pads 711 at the bottom surface thereof. The chip pads 711 may include, for example, a metal. The upper package 20 may further include conductive bumps 750. The conductive bumps 750 may be provided between the upper substrate 700 and the semiconductor element 710 and connected to the second substrate pads 702 and the chip pads 711 of the semiconductor element 710. The conductive bumps 750 may include a solder material.

Connection bumps 675 may be arranged between the second substrate 600 and the upper substrate 700. For example, the connection bumps 675 may be provided between the second redistribution pads 650 and the first substrate pads 701 and connected to the second redistribution pads 650 and the first substrate pads 701. Therefore, the semiconductor element 710 may be electrically connected to the upper semiconductor chip 220, the lower semiconductor chip 210, or the first substrate 100 through the connection bumps 675. Any one of the connection bumps 675 may be bonded to the ground redistribution pad 650G. The upper package 20 may be configured to receive a ground voltage through the first lower conductive structures 311, the conductive layer 350, the ground redistribution patterns 630G, and the ground redistribution pad 650G.

The molding pattern 740 may be provided on the upper substrate 700 and cover the semiconductor element 710. The molding pattern 740 may expose the top surface of a second semiconductor chip 720. The molding pattern 740 may include an insulation polymer such as an EMC.

The upper package 20 may further include a heat dissipation structure 790. The heat dissipation structure 790 may be disposed on the top surface of the second semiconductor chip 720 and the top surface of the molding pattern 740. The heat dissipation structure 790 may extend further onto the side surfaces of molding pattern 740. The heat dissipation structure 790 may include a heat sink, a heat slug, or a thermal interface material (TIM) layer. The heat dissipation structure 790 may include, for example, a metal.

According to embodiments, the conductive bumps 750 may be omitted, and the semiconductor element 710 may be electrically connected to the upper substrate 700 through bonding wires. In this case, the chip pads 711 of the semiconductor element 710 may be provided on the top surface of the semiconductor element 710.

Hereinafter, a method of manufacturing a semiconductor package, according to embodiments, will be described.

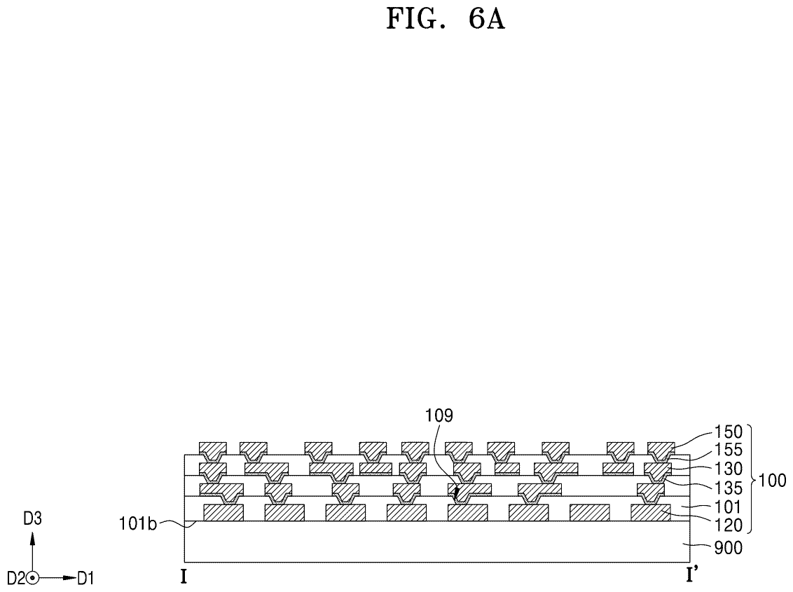

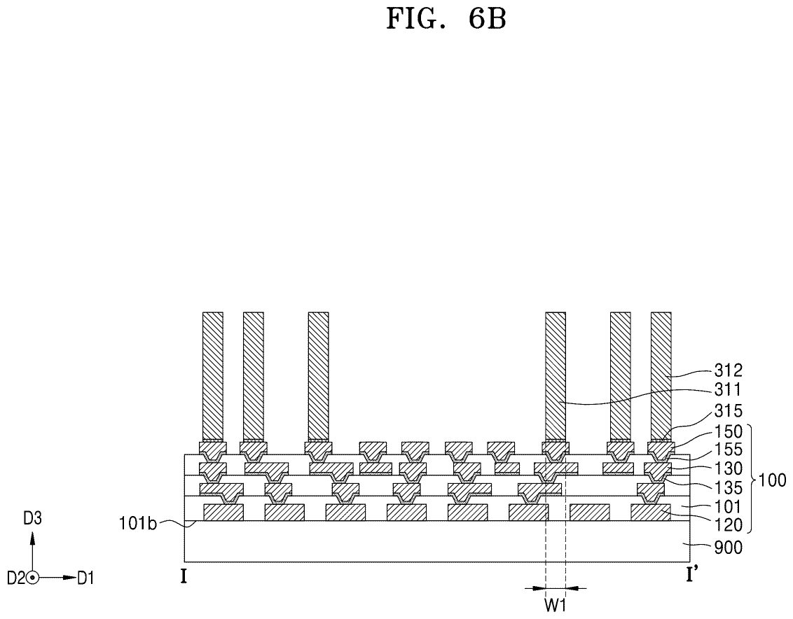

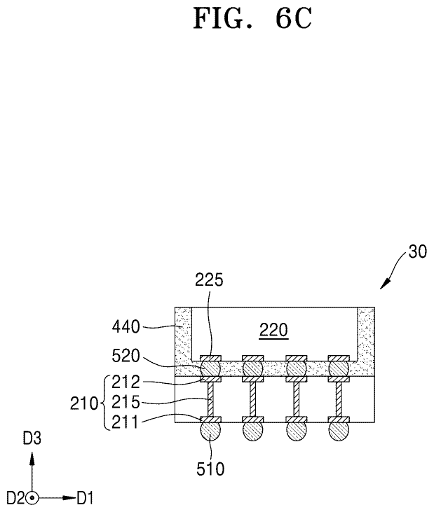

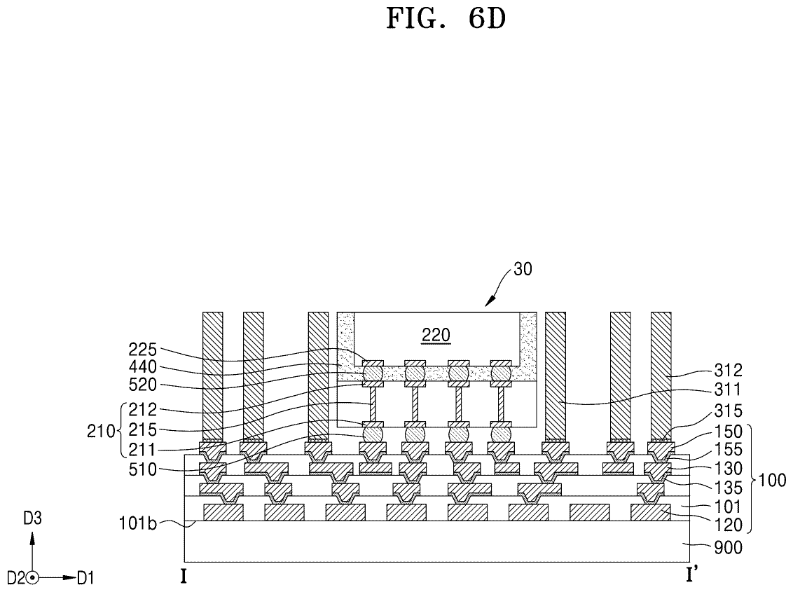

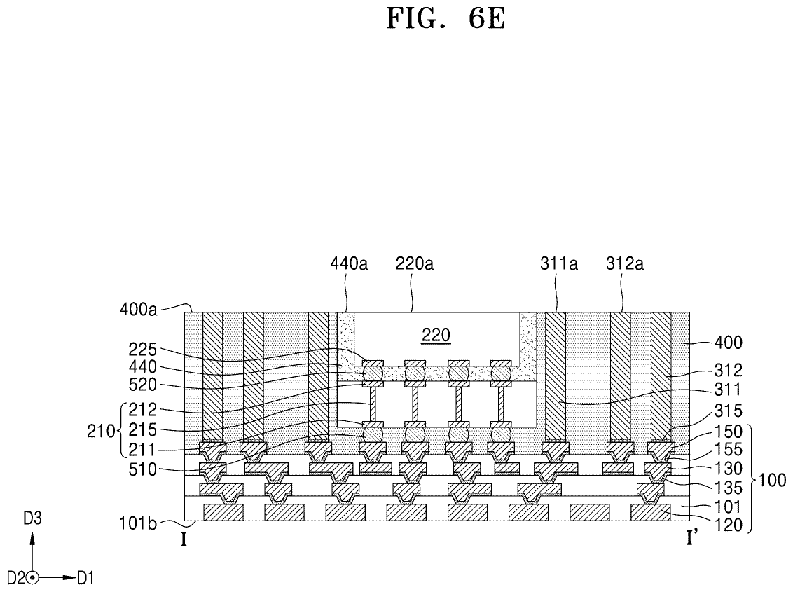

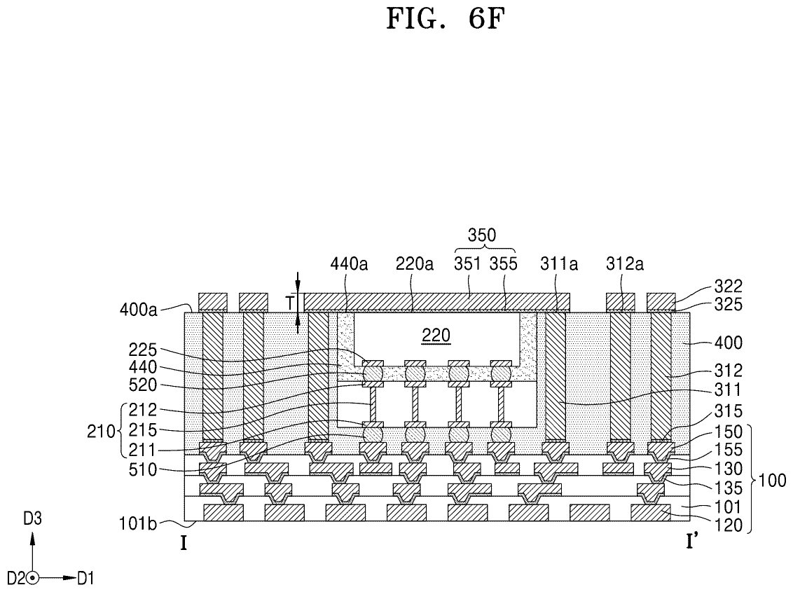

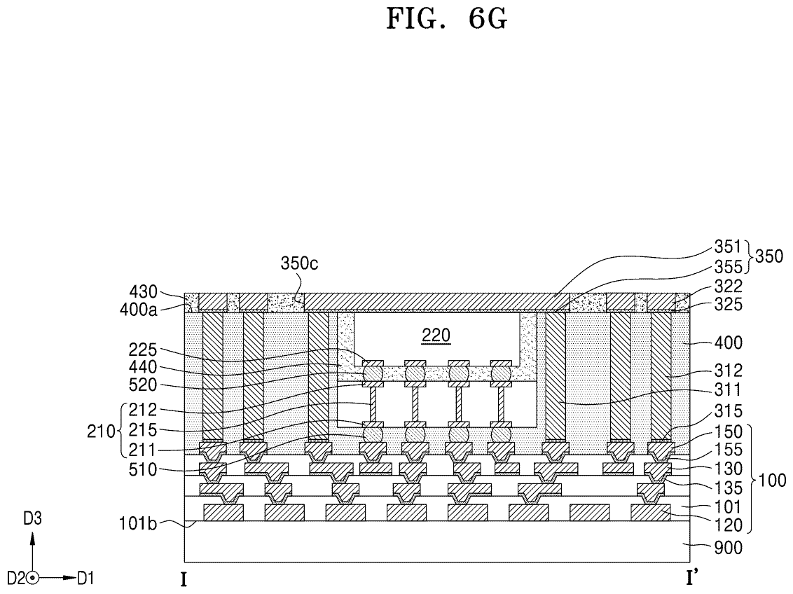

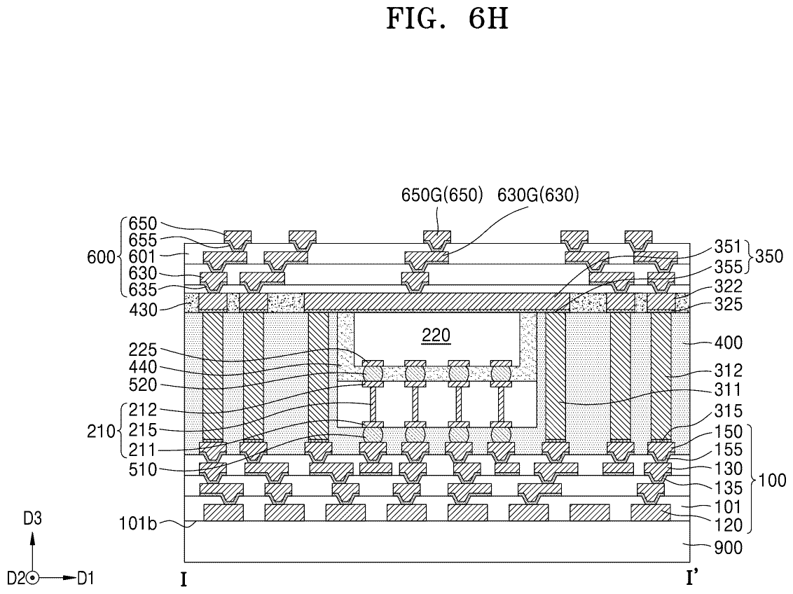

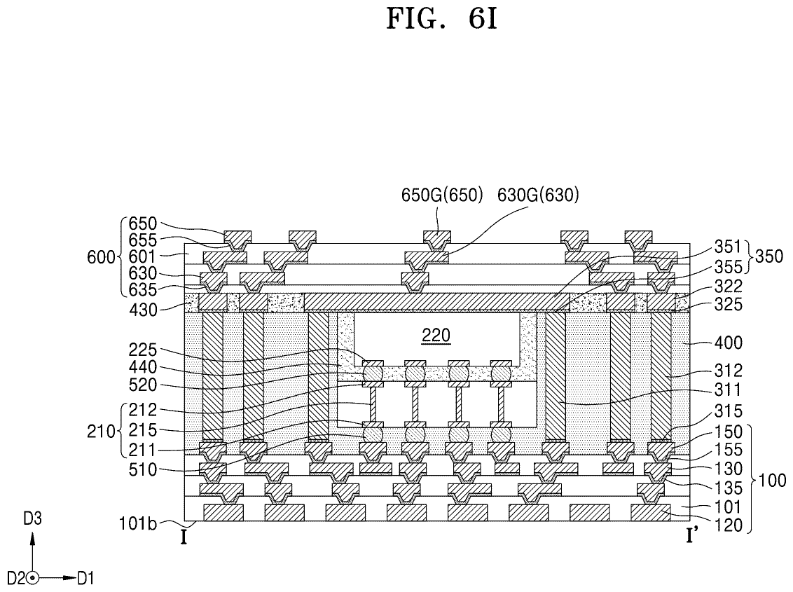

FIGS. 6A to 6I are diagrams illustrating a method of manufacturing a semiconductor package, according to embodiments, which correspond to cross-sections taken along a line I-I′ of FIG. 1A or FIG. 1E.

Referring to FIG. 6A, the under bump patterns 120, the first insulation layer 101, the first seed patterns 135, and the first redistribution patterns 130 may be formed on a carrier substrate 900. According to embodiments, the under bump patterns 120 may be formed on the carrier substrate 900 through an electroplating process. The first insulation layer 101 may be formed on the carrier substrate 900 and cover the sidewalls and the top surfaces of the under bump patterns 120. Openings 109 may be formed in the first insulation layer 101 and expose the under bump patterns 120. The first seed patterns 135 may be formed within the openings 109 and on the top surface of the first insulation layer 101. The first redistribution patterns 130 may be formed on the first seed patterns 135 by performing an electroplating process using the first seed patterns 135 as electrodes.

Thereafter, the processes of forming the first insulation layer 101, forming the first seed patterns 135, and forming the first redistribution patterns 130 may be repeatedly performed. Therefore, first insulation layers 101 and first redistribution patterns 130 may be formed and stacked. The first seed patterns 135 may be formed on the bottom surfaces of the first redistribution patterns 130, respectively.

The first redistribution pads 150 may be formed in and on the uppermost one of the first insulation layers 101 and connected to the first redistribution patterns 130. Before the first redistribution pads 150 are formed, the first seed pads 155 may be formed. The first redistribution pads 150 may be formed by performing an electroplating process using the first seed pads 155 as electrodes. Therefore, the first substrate 100 may be manufactured. The first substrate 100 may include the first insulation layers 101, the under bump patterns 120, the first seed patterns 135, the first redistribution patterns 130, the first seed pads 155, and the first redistribution pads 150.

Referring to FIG. 6B, the lower seed patterns 315 may be formed on the first redistribution pads 150. The first lower conductive structures 311 and the second lower conductive structures 312 may be formed by performing an electroplating process using the lower seed patterns 315 as electrodes. The first lower conductive structures 311 and the second lower conductive structures 312 may be formed on the lower seed patterns 315, respectively. For example, the second lower conductive structures 312 and the first lower conductive structures 311 may be formed through a single process. Therefore, the process of manufacturing a semiconductor package may be simplified. The second lower conductive structures 312 may include the same material as the material of the first lower conductive structures 311. The width of the second lower conductive structures 312 may be identical to or different from the first width W1.

Referring to FIG. 6C, a chip stack 30 may be prepared. The chip stack 30 may include the lower semiconductor chip 210 and the upper semiconductor chip 220. The upper semiconductor chip 220 may be disposed on the lower semiconductor chip 210. The chip stack 30 may further include at least one of the lower solder bumps 510, the first upper solder bumps 520, and the internal molding film 440. The lower semiconductor chip 210, the upper semiconductor chip 220, the lower solder bumps 510, the first upper solder bumps 520, and the internal molding film 440 may be identical to those described above with reference to the embodiment of FIGS. 1A to 1B. For example, the lower semiconductor chip 210 may include the lower pads 211, the through vias 215, and the upper pads 212. The upper semiconductor chip 220 may include the chip pads 225.

Referring to FIG. 6D, the chip stack 30 may be disposed on the top surface of the center region of the first substrate 100. The chip stack 30 may be disposed between the first lower conductive structures 311. At this time, the arrangement of the chip stack 30 may be adjusted, such that the lower solder bumps 510 are vertically aligned with corresponding first redistribution pads 150. The lower solder bumps 510 may be bonded to corresponding first redistribution pads 150. The lower solder bumps 510 may be bonded, for example, through a reflow process. Therefore, the lower semiconductor chip 210 may be mounted on the first substrate 100.

Referring to FIG. 6E, the molding film 400 may be formed on the top surface of the first substrate 100 and cover the sidewalls of the lower semiconductor chip 210, the sidewalls of the internal molding film 440, and the sidewalls of the first lower conductive structures 311 and the second lower conductive structures 312. The molding film 400 may further cover the sidewalls of the lower solder bumps 510. Formation of the molding film 400 may include performing a grinding process on the top surface of the molding film 400. The first lower conductive structures 311, the second lower conductive structures 312, the upper semiconductor chip 220, and the internal molding film 440 may be ground together with the molding film 400. Therefore, after the grinding process is completed, a top surface 400a of the molding film 400, the top surfaces 311a of the first lower conductive structures 311, the top surfaces 312a of the second lower conductive structures 312, a top surface 220a of the upper semiconductor chip 220, and a top surface 440a of the internal molding film 440 may be provided substantially at the same level.

Referring to FIG. 6F, the conductive layer 350, the upper seed patterns 325, and the second upper conductive structures 322 may be formed. For example, a preliminary seed film (not shown) may be formed on the top surface 400a of the molding film 400, the top surfaces 311a of the first lower conductive structures 311, the top surfaces 312a of the second lower conductive structures 312, the top surface 220a of the upper semiconductor chip 220, and the top surface 440a of the internal molding film 440. A photoresist pattern may be formed on the preliminary seed film. The photoresist pattern may have resist openings that expose the top surface of the preliminary seed film. A plating process using the preliminary seed film as an electrode may be performed, thereby forming a metal layer 351 and the second upper conductive structures 322. The metal layer 351 and the second upper conductive structures 322 may each be formed within the resist openings and on the preliminary seed film. Afterwards, the photoresist pattern may be removed through a stripping process, and thus portions of the preliminary seed film may be exposed. The exposed portions of the preliminary seed film may be removed through an etching process, thereby exposing the top surface 400a of the molding film 400. Other portions of the preliminary seed film are provided on the bottom surface of the conductive layer 350 or the bottom surfaces of the second upper conductive structures 322, and thus the other portions of the preliminary seed film may not be exposed to the etching process. The other portions of the preliminary seed film may remain after the etching process. The other portions of the preliminary seed film may constitute the seed layer 355 and the upper seed patterns 325. Therefore, the conductive layer 350, the upper seed patterns 325, and the second upper conductive structures 322 may be manufactured. The conductive layer 350 may include the seed layer 355 and the metal layer 351. The thickness T of the conductive layer 350 may be equal to the sum of the thicknesses of the upper seed patterns 325 and the thicknesses of the second upper conductive structures 322, but is not limited thereto.

A plating process for forming the metal layer 351 and the second upper conductive structures 322 may be performed under different conditions from the plating process for forming the first lower conductive structures 311 and the second lower conductive structures 312 described with reference to FIG. 6B. Therefore, the grains 351G of the metal layer 351 may be different from the grains 311G of the first lower conductive structures 311, as described with reference to the embodiment of FIG. 1C. The grains 322G of the second upper conductive structures 322 may be different from the grains 312G of the second lower conductive structures 312. For example, the size of the grains 351G of the metal layer 351 may be smaller than the size of the grains 311G of the first lower conductive structures 311, and the size of the grains 322G of the second upper conductive structures 322 may be smaller than the size of the grains 312G of the second lower conductive structures 312.

Referring to FIG. 6G, the insulation sealing film 430 may be formed on the top surface 400a of the molding film 400 and cover the sidewalls 350c of the conductive layer 350, the sidewalls of the upper seed patterns 325, and the sidewalls of the second upper conductive structures 322. The insulation sealing film 430 may further cover the top surface of the conductive layer 350 or the top surfaces of the second upper conductive structures 322, but is not limited thereto.

Referring to FIG. 6H, the second insulation layers 601, the second seed patterns 635, the second redistribution patterns 630, the second seed pads 655, and the second redistribution pads 650 may be formed on the conductive layer 350, the second upper conductive structures 322, and the insulation sealing film 430, and thus the second substrate 600 may be manufactured. The second insulation layers 601, the second seed patterns 635, the second redistribution patterns 630, the second seed pads 655, and the second redistribution pads 650 may be formed in the substantially same regards as the first insulation layers 101, the first seed patterns 135, the first redistribution patterns 130, the first seed pads 155, and the first redistribution pads 150 described above with reference to FIG. 6A, respectively. The ground redistribution pad 650G may be electrically connected to the conductive layer 350 through the ground redistribution patterns 630G. The remaining second redistribution pads 650 may be electrically connected to the second upper conductive structures 322 through the remaining second redistribution patterns 630, respectively.

Referring to FIG. 6I, the carrier substrate 900 may be removed, and thus the bottom surface of the first substrate 100 may be exposed. For example, the bottom surface 101b of the lowermost one of the first insulation layers 101 and the bottom surfaces of the under bump patterns 120 may be exposed. The process of forming the first substrate 100, the electroplating process for forming the first lower conductive structures 311 and the second lower conductive structures 312, the process of forming the molding film 400, the electroplating process for forming the metal layer 351 and the second upper conductive structures 322, the process of forming the insulation sealing film 430, and the process of forming the second substrate 600 described above with reference to FIGS. 6A to 6H may be performed at the wafer level. In this case, after the carrier substrate 900 is removed, a sawing process may be further performed.

Referring back to FIG. 1B, the solder ball terminals 500 may be formed on the bottom surface of the first substrate 100 and connected to the under bump patterns 120. The semiconductor package 10 may be manufactured according to the embodiments described above.

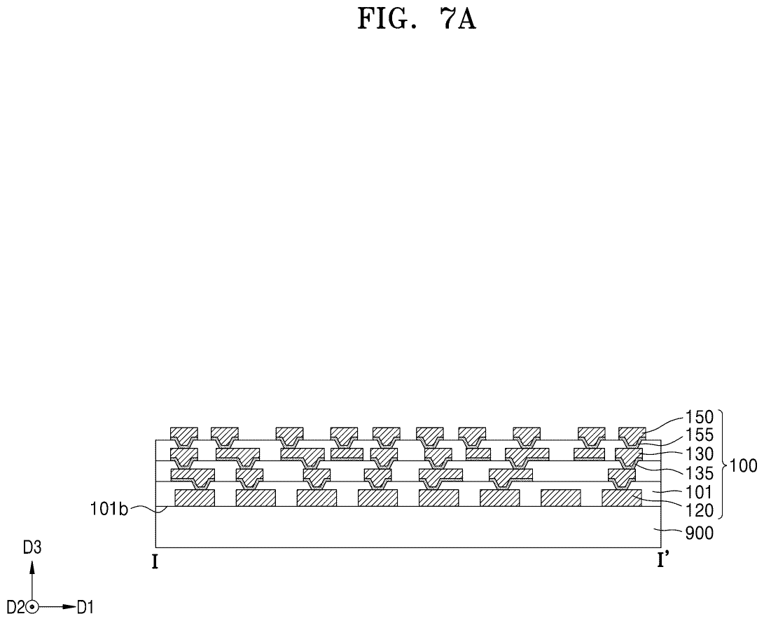

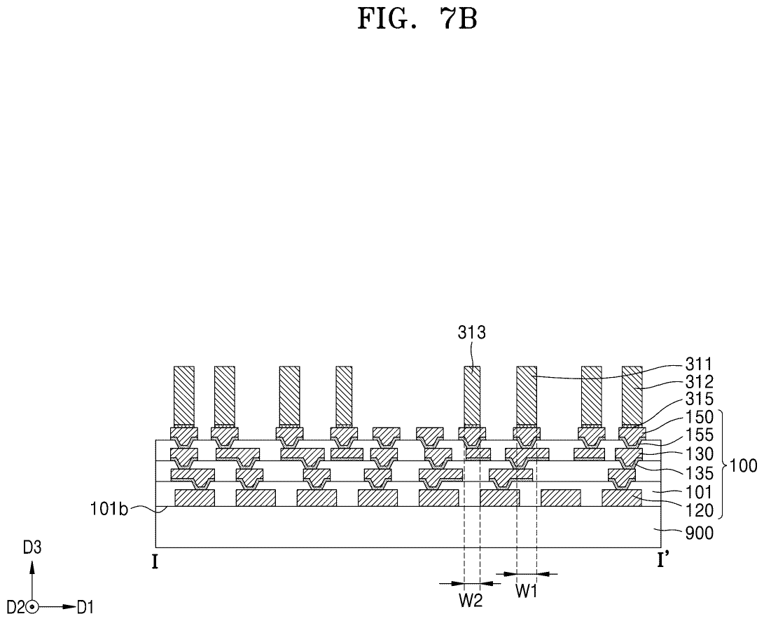

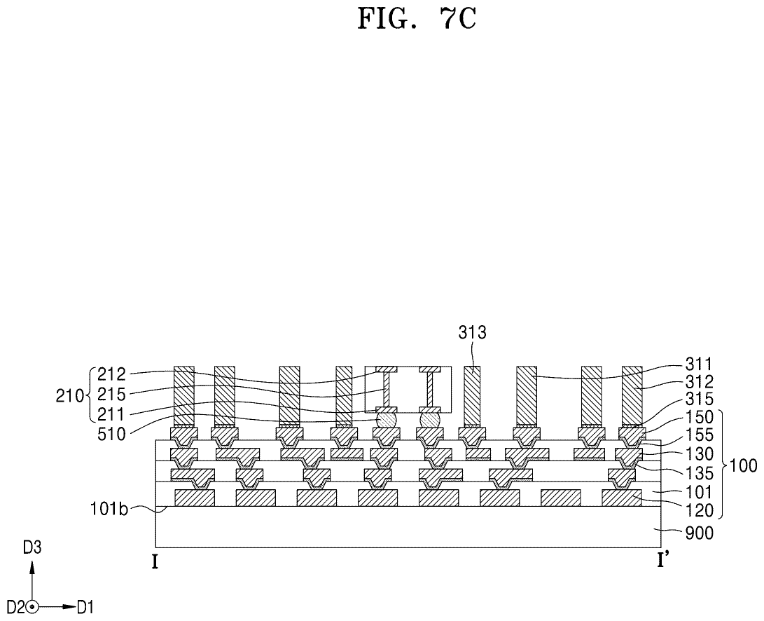

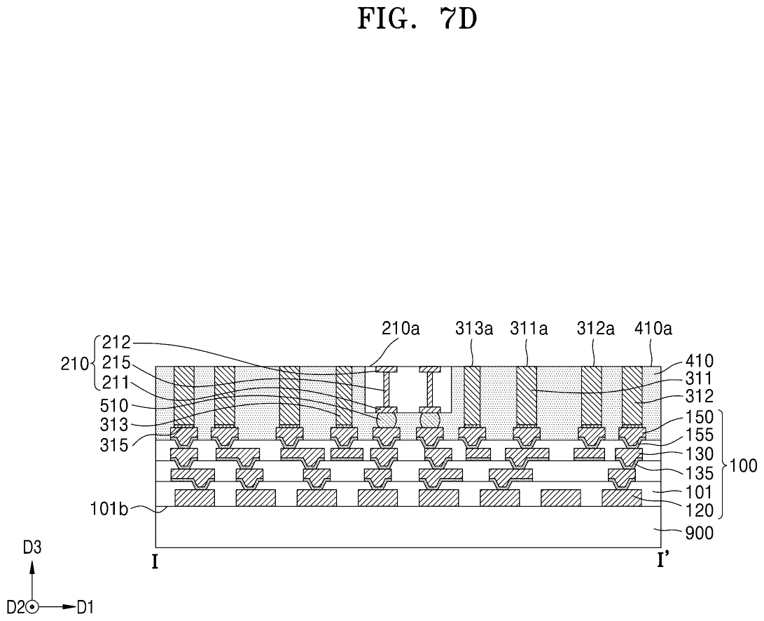

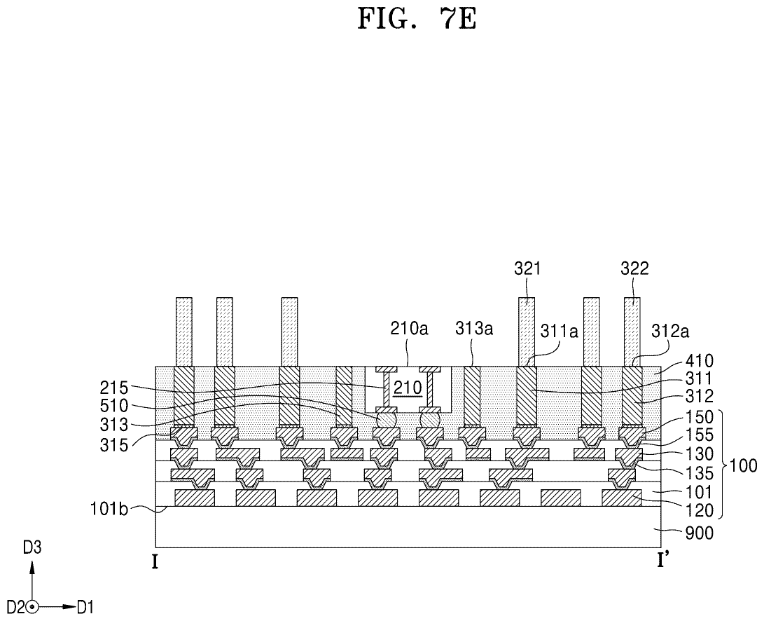

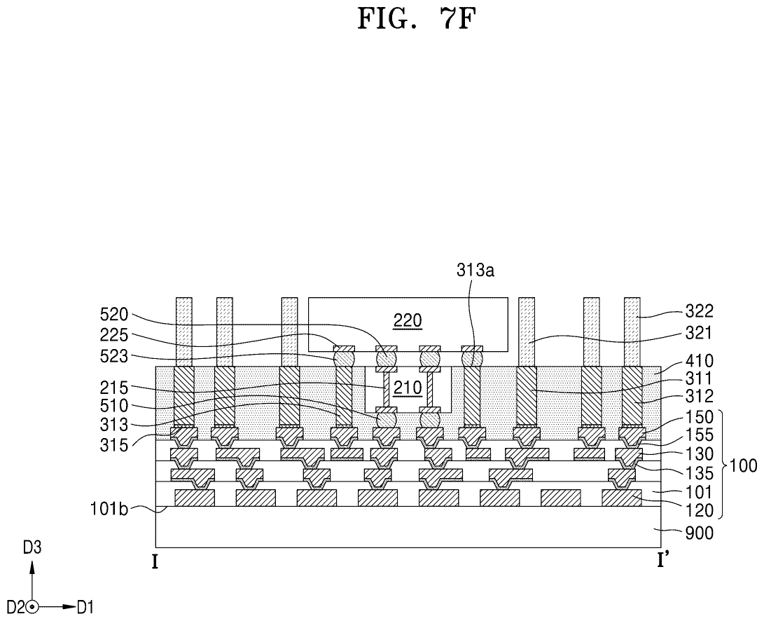

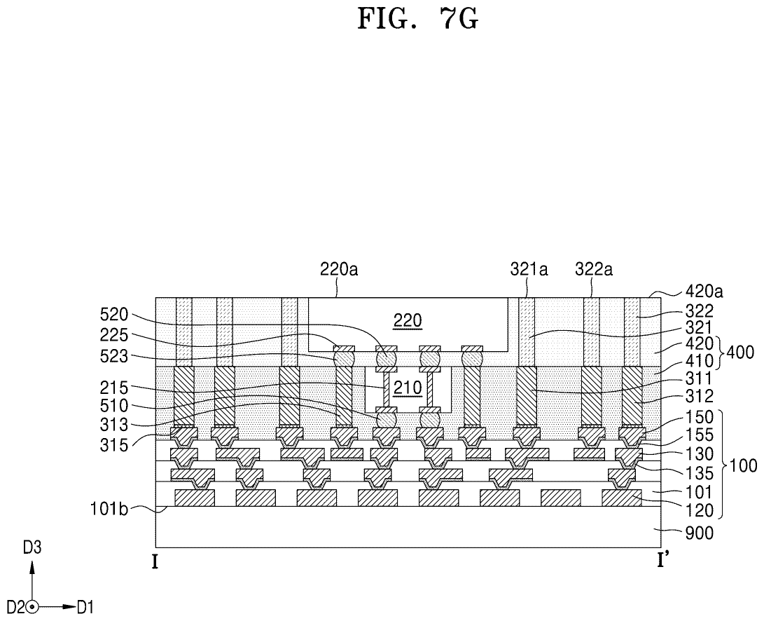

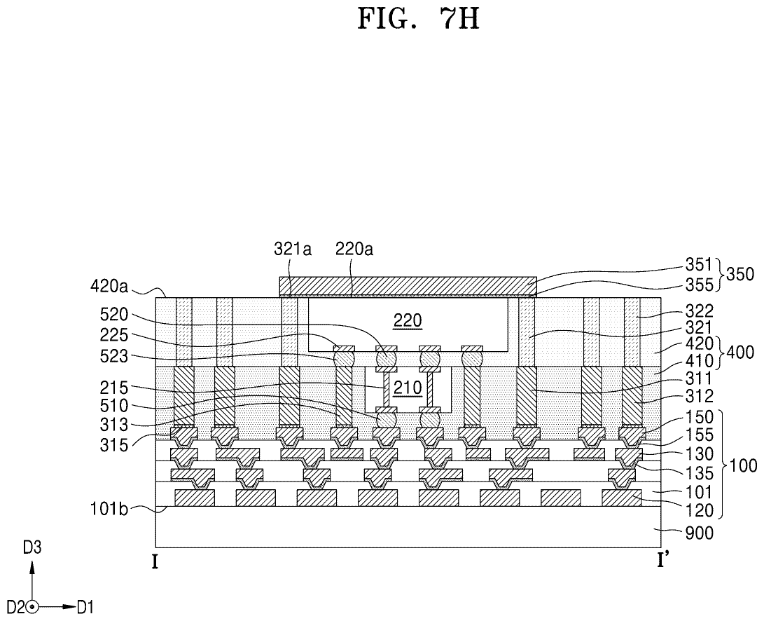

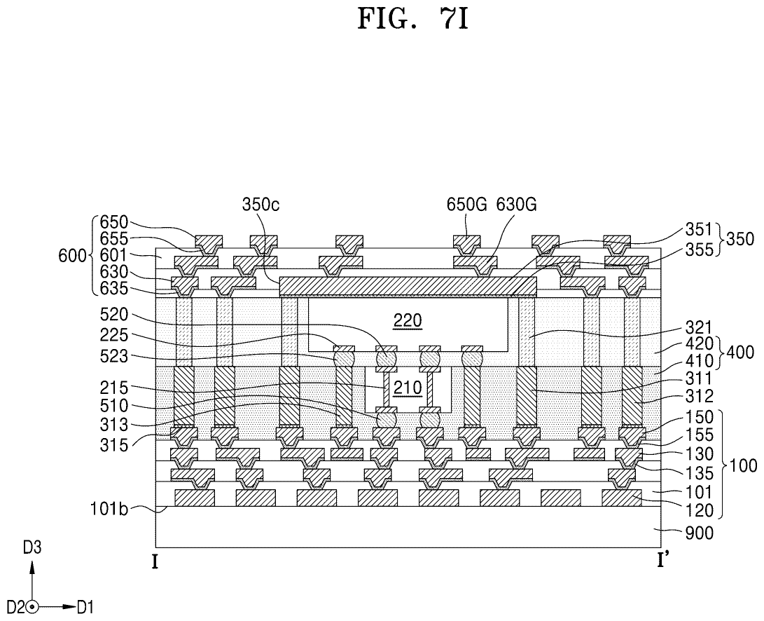

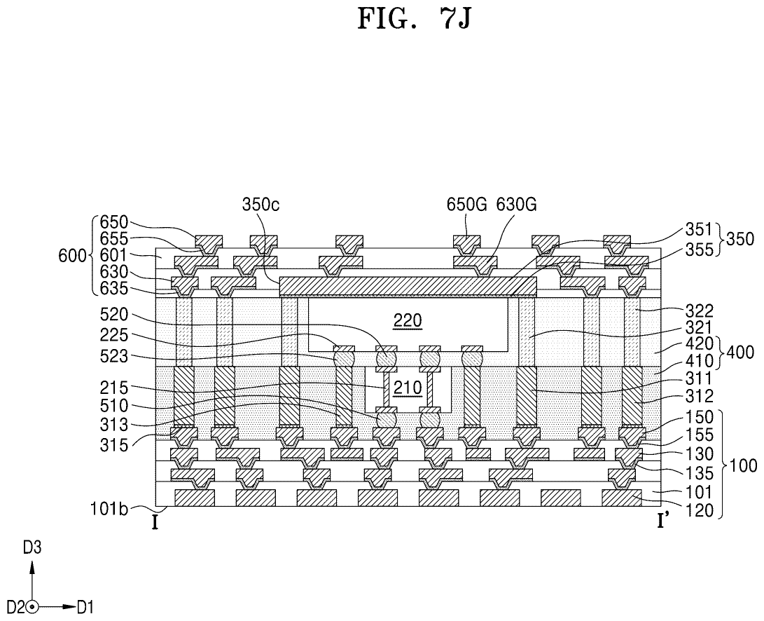

FIGS. 7A to 7J are diagrams illustrating a method of manufacturing a semiconductor package, according to embodiments, which correspond to cross-sections taken along a line I-I′ of FIG. 1A or FIG. 1E.

Referring to FIG. 7A, the under bump patterns 120, the first insulation layers 101, the first seed patterns 135, the first redistribution patterns 130, the first seed pads 155, and the first redistribution pads 150 are formed on the carrier substrate 900, and thus the first substrate 100 may be manufactured. The first substrate 100 may be manufactured in the substantially same regard as described with reference to the embodiment of FIG. 6A.

Referring to FIG. 7B, the lower seed patterns 315 may be formed on the first redistribution pads 150. The first lower conductive structures 311, the second lower conductive structures 312, and the third lower conductive structures 313 may be formed by performing an electroplating process using the lower seed patterns 315 as electrodes. The first lower conductive structures 311, the second lower conductive structures 312, and the third lower conductive structures 313 may be formed on the lower seed patterns 315, respectively. For example, the first lower conductive structures 311, the second lower conductive structures 312, and the third lower conductive structures 313 may be formed through a single plating process. Therefore, the process of manufacturing a semiconductor package may be simplified. The third lower conductive structures 313 may include the same material as the material of the first lower conductive structures 311 and the second lower conductive structures 312. The width W2 of each of the third lower conductive structures 313 may be smaller than the first width W1.

Referring to FIG. 7C, the lower semiconductor chip 210 may be disposed on the top surface of the center region of the first substrate 100. The lower semiconductor chip 210 may include the lower pads 211, the through vias 215, and the upper pads 212. The lower semiconductor chip 210 may be disposed between the third lower conductive structures 313. The lower solder bumps 510 may be formed between the first substrate 100 and the lower semiconductor chip 210 and electrically connect the lower semiconductor chip 210 to the first substrate 100.

Referring to FIG. 7D, the lower molding film 410 may be formed on the top surface of the first substrate 100 and cover the sidewalls of the first lower conductive structures 311, the second lower conductive structures 312, and the third lower conductive structures 313 and the sidewalls of the lower semiconductor chip 210. The lower molding film 410 may further extend into the first gap region between the first substrate 100 and the lower semiconductor chip 210. According to embodiments, the lower molding film 410 may further cover the top surfaces of the first lower conductive structures 311, the second lower conductive structures 312, and the third lower conductive structures 313 and the top surface of the lower semiconductor chip 210.

A grinding process may be performed on the lower molding film 410, and thus a portion of the lower molding film 410 may be removed. For example, the grinding process may be performed through a chemical mechanical polishing process. The top surfaces 311a of the first lower conductive structures 311, the top surfaces 312a of the second lower conductive structures 312, top surfaces 313a of the third lower conductive structures 313, and a top surface 210a of the lower semiconductor chip 210 may be ground together with the molding film 400. After the grinding process is completed, the top surfaces 311a of the first lower conductive structures 311, the top surfaces 312a of the second lower conductive structures 312, the top surfaces 313a of the third lower conductive structures 313, the top surface 210a of the lower semiconductor chip 210, and a top surface 410a of the lower molding film 410 may be provided at substantially the same level.

Referring to FIG. 7E, the first upper conductive structures 321 may be formed on the first lower conductive structures 311, respectively. The second upper conductive structures 322 may be formed on the second lower conductive structures 312, respectively. For example, an electroplating process using the first lower conductive structures 311 as electrodes may be performed to form the first upper conductive structures 321. In this case, the first upper conductive structures 321 may directly contact the top surfaces 311a of the first lower conductive structures 311.

An electroplating process using the second lower conductive structures 312 as electrodes may be performed to form the second upper conductive structures 322. In this case, the second upper conductive structures 322 may directly contact the top surfaces 312a of the second lower conductive structures 312. For example, the second upper conductive structures 322 and the first upper conductive structures 321 may be formed through a single plating process.

In another example, upper seed patterns 325 (refer to FIG. 4D or FIG. 4E) may be formed on the first lower conductive structures 311 and the second lower conductive structures 312. An electroplating process using the upper seed patterns 325 as electrodes may be performed to form the first upper conductive structures 321 and the second upper conductive structures 322. The first upper conductive structures 321 and the second upper conductive structures 322 may not be formed on the third lower conductive structures 313.

Referring to FIG. 7F, the upper semiconductor chip 220 may be disposed on the lower semiconductor chip 210 and the third lower conductive structures 313. The first upper solder bumps 520 may be formed between the lower semiconductor chip 210 and the upper semiconductor chip 220. The second upper solder bumps 523 may be formed between the top surfaces 313a of the third lower conductive structures 313 and the upper semiconductor chip 220.

Referring to FIG. 7G, the upper molding film 420 may be formed on the top surface of the lower molding film 410 and cover the sidewalls of the first upper conductive structures 321 and the second upper conductive structures 322 and the sidewalls of the upper semiconductor chip 220. Therefore, the molding film 400 including the lower molding film 410 and the upper molding film 420 may be manufactured. The upper molding film 420 may further extend into the second gap region between the lower semiconductor chip 210 and the upper semiconductor chip 220. A grinding process may be performed on the upper molding film 420, and thus a portion of the upper molding film 420 may be removed. For example, the grinding process may be performed through a chemical mechanical polishing process. The first upper conductive structures 321, the second upper conductive structures 322, and the upper semiconductor chip 220 may be ground together with the upper molding film 420. As a result of the grinding process, top surfaces 321a of the first upper conductive structures 321, top surfaces 322a of the second upper conductive structures 322, and the top surface 220a of the upper semiconductor chip 220 may be exposed. After the grinding process is completed, the top surfaces 321a of the first upper conductive structures 321, the top surfaces 322a of the second upper conductive structures 322, the top surface 220a of the upper semiconductor chip 220, and a top surface 420a of the upper molding film 420 may be provided at substantially the same level.

Referring to FIG. 7H, the conductive layer 350 may be formed on the top surface 220a of the upper semiconductor chip 220 and the top surfaces 321a of the first upper conductive structures 321. The conductive layer 350 may further cover a portion of the top surface 420a of the upper molding film 420. Formation of the conductive layer 350 may include formation of the seed layer 355 and formation of the metal layer 351. The formation of the metal layer 351 may include performing a plating process using the seed layer 355 as an electrode. The plating process for forming the metal layer 351 may be performed under different conditions from the plating process for forming the first lower conductive structures 311 and the second lower conductive structures 312 described with reference to FIG. 7B and the plating process for forming the first upper conductive structures 321 and the second upper conductive structures 322 described with reference to FIG. 7E. Therefore, the grains 351G of the metal layer 351 may be different from the grains 311G of the first lower conductive structures 311 and the grains 321G of the first upper conductive structures 321, as described with reference to the embodiment of FIG. 4C. For example, the size of the grains 351G of the metal layer 351 may be larger than the size of the grains 311G of the first lower conductive structures 311 and the size of the grains 321G of the first upper conductive structures 321.

For example, a photoresist pattern may be further formed before or after the seed layer 355 is formed. The conductive layer 350 may be formed within an opening of the photoresist pattern, but embodiments of the present disclosure are not limited thereto. Thereafter, the photoresist pattern may be removed. The conductive layer 350 may not be formed on the second upper conductive structures 322 and may be spaced apart from the second upper conductive structures 322.

Referring to FIG. 7I, the second insulation layers 601, the second seed patterns 635, the second redistribution patterns 630, the second seed pads 655, and the second redistribution pads 650 may be formed on the conductive layer 350, the second upper conductive structures 322, and the upper molding film 420, and thus the second substrate 600 may be manufactured. The ground redistribution pad 650G may be electrically connected to the conductive layer 350 through the ground redistribution patterns 630G. The remaining second redistribution pads 650 may be electrically connected to the second upper conductive structures 322 through the remaining second redistribution patterns 630, respectively.

Referring to FIG. 7J, the carrier substrate 900 may be removed, and thus the bottom surface of the first substrate 100 may be exposed. For example, the bottom surface 101b of the lowermost one of the first insulation layers 101 and the bottom surfaces of the under bump patterns 120 may be exposed. The process of forming the first substrate 100, the electroplating process for forming the first lower conductive structures 311, the second lower conductive structures 312, and the third lower conductive structures 313, the process of forming the lower molding film 410, the electroplating process for forming the first upper conductive structures 321 and the second upper conductive structures 322, the process of forming the upper molding film 420, and the process of forming the metal layer 351 described above with reference to FIGS. 7A to 7H may be performed at the wafer level. In this case, after the carrier substrate 900 is removed, a sawing process may be further performed.

Referring back to FIG. 4B, the solder ball terminals 500 may be formed on the bottom surface of the first substrate 100 and connected to the under bump patterns 120. The semiconductor package 10G may be manufactured according to the embodiments described above.

While non-limiting example embodiments of the present disclosure has been particularly shown and described, it will be understood that various changes in form and details may be made therein without departing from the spirit and scope of the present disclosure.

What is claimed is:

1. A semiconductor package comprising:
a first substrate;
a lower semiconductor chip on the first substrate and comprising a through via;
an upper semiconductor chip on the lower semiconductor chip and connected to the through via;
a first lower conductive structure on the first substrate and laterally spaced apart from the lower semiconductor chip;
a second lower conductive structure on the first substrate and laterally spaced apart from the lower semiconductor chip and the first lower conductive structure;
an upper conductive structure on the second lower conductive structure;
a conductive layer in direct physical contact with a top surface of the upper semiconductor chip and electrically connected to the first lower conductive structure; and
a second substrate on the conductive layer and electrically connected to the upper conductive structure.

2. The semiconductor package of claim 1, wherein the semiconductor package is configured to have a ground voltage supplied to the conductive layer through the first substrate and the first lower conductive structure.

3. The semiconductor package of claim 1, wherein the second substrate comprises a second insulation layer, second redistribution patterns, and second redistribution pads,
wherein the second redistribution patterns comprise a ground redistribution pattern on the conductive layer and connected to the conductive layer, and
wherein the second redistribution pads comprise a ground redistribution pad vertically overlapping the conductive layer and connected to the ground redistribution pattern.

4. The semiconductor package of claim 3, further comprising:
an upper package on the second substrate and comprising an upper substrate and a semiconductor device; and
connection bumps between the second substrate and the upper package and connected to the upper package,
wherein at least one of the connection bumps is connected to the ground redistribution pad.

5. The semiconductor package of claim 1, wherein the conductive layer is in physical contact with 20% to 100% of the top surface of the upper semiconductor chip.

6. The semiconductor package of claim 1, wherein the conductive layer comprises:
first portions extending parallel to a first direction in a plan view; and
second portions extending parallel to a second direction in the plan view and connected to the first portions,
wherein the first portions are spaced apart from each other in the second direction, and
wherein the second direction intersects the first direction.

7. The semiconductor package of claim 1, wherein the conductive layer comprises a seed layer and a metal layer on the seed layer, and
wherein a size of grains of the metal layer is larger than a size of grains of the first lower conductive structure.

8. The semiconductor package of claim 1, further comprising:
an internal molding film on a top surface of the lower semiconductor chip and covering sidewalls of the upper semiconductor chip; and
a molding film on the first substrate and covering sidewalls of the first lower conductive structure and sidewalls of the second lower conductive structure,
wherein the molding film is spaced apart from the top surface of the upper semiconductor chip.

9. The semiconductor package of claim 8, wherein the conductive layer is in direct contact with a top surface of the internal molding film.

10. The semiconductor package of claim 8, wherein a top surface of the molding film is coplanar with a top surface of the first lower conductive structure, a top surface of the second lower conductive structure, and the top surface of the upper semiconductor chip.

11. A semiconductor package comprising:
a first redistribution substrate;
a lower semiconductor chip on the first redistribution substrate and comprising a through via;
an upper semiconductor chip on the lower semiconductor chip and connected to the lower semiconductor chip;
a first lower conductive structure on the first redistribution substrate and laterally spaced apart from the lower semiconductor chip; and
a conductive layer in physical contact with a top surface of the upper semiconductor chip and electrically connected to the first lower conductive structure.

12. The semiconductor package of claim 11, wherein the semiconductor package is configured to have a ground voltage applied to the first lower conductive structure and the conductive layer.

13. The semiconductor package of claim 12, further comprising:
a second lower conductive structure on the first redistribution substrate and laterally spaced apart from the lower semiconductor chip and the first lower conductive structure;
a third lower conductive structure on the first redistribution substrate and between the lower semiconductor chip and the first lower conductive structure;
a first upper conductive structure on the first lower conductive structure; and
a second upper conductive structure on the second lower conductive structure,
wherein the upper semiconductor chip is on the third lower conductive structure and is electrically connected to the third lower conductive structure, and
wherein a width of the upper semiconductor chip is greater than a width of the lower semiconductor chip.

14. The semiconductor package of claim 13, wherein a width of the first lower conductive structure is greater than a width of the third lower conductive structure,
wherein the width of the third lower conductive structure is greater than a width of the through via, and
wherein the semiconductor package is configured such that a power voltage is applied to the third lower conductive structure.

15. The semiconductor package of claim 13, further comprising:
a lower molding film on the first redistribution substrate and covering sidewalls of the first lower conductive structure, sidewalls of the second lower conductive structure, sidewalls of the third lower conductive structure, and sidewalls of the lower semiconductor chip; and
an upper molding film on the lower molding film and covering sidewalls of the first upper conductive structure, sidewalls of the second upper conductive structure, and sidewalls of the upper semiconductor chip,
wherein a top surface of the upper molding film is coplanar with the top surface of the upper semiconductor chip, and
wherein the conductive layer is in direct physical contact with at least a portion of the top surface of the upper molding film.

16. A semiconductor package comprising:
a first redistribution substrate comprising a first insulation layer, a first seed pattern, and a first conductive pattern on the first seed pattern, the first insulation layer comprising a photosensitive polymer;
solder ball terminals on a bottom surface of the first redistribution substrate;
a lower semiconductor chip on a top surface of the first redistribution substrate and comprising a lower pad, a through via, and an upper pad;
an upper semiconductor chip on a top surface of the lower semiconductor chip and connected to the through via;
a first lower conductive structure on the first redistribution substrate and laterally spaced apart from the lower semiconductor chip;
a second lower conductive structure on the first redistribution substrate and laterally spaced apart from the lower semiconductor chip and the first lower conductive structure, the first lower conductive structure being between the lower semiconductor chip and the second lower conductive structure;
an upper conductive structure on the second lower conductive structure;
a molding film on the first redistribution substrate and covering sidewalls of the lower semiconductor chip, sidewalls of the first lower conductive structure, and sidewalls of the second lower conductive structure, the molding film being spaced apart from a top surface of the upper semiconductor chip;
a conductive layer on the upper semiconductor chip and in direct contact with the top surface of the upper semiconductor chip; and
a second redistribution substrate on the molding film and the conductive layer and comprising a second insulation layer, second seed patterns, second redistribution patterns on the second seed patterns, and second redistribution pads,
wherein the conductive layer comprises:
a seed layer in direct contact with the top surface of the upper semiconductor chip; and
a metal layer on the seed layer.

17. The semiconductor package of claim 16, wherein the semiconductor package is configured such that a ground voltage is supplied to the conductive layer through the first redistribution substrate and the first lower conductive structure.

18. The semiconductor package of claim 16, wherein a contact area between the conductive layer and the upper semiconductor chip is in a range of 20% to 100% of a total planar area of the top surface of the upper semiconductor chip.

19. The semiconductor package of claim 16, wherein the second redistribution patterns comprise a ground redistribution pattern on the conductive layer and connected to the conductive layer, and
wherein the second redistribution pads comprise a ground redistribution pad vertically overlapping the conductive layer and connected to the ground redistribution pattern.

20. The semiconductor package of claim 16, wherein a thickness of the conductive layer is in a range of 10 μm to 100 μm.
